(19) United States
(12) Patent Application Publication
(10) Pub. No.: US 2026/0096037 A1
(43) Pub. Date: Apr. 2, 2026

(54) FOLDABLE ELECTRONIC DEVICE INCLUDING DISPLAY MODULE

(71) Applicant: Samsung Electronics Co., Ltd., Suwon-si (KR)

(72) Inventors: Jaehyun BAE, Suwon-si (KR); Kwangjin BAE, Suwon-si (KR); Yonggeon LEE, Suwon-si (KR); Changsu LEE, Suwon-si (KR); Hyunsuk CHOI, Suwon-si (KR)

(21) Appl. No.: 19/325,895

(22) Filed: Sep. 11, 2025

Related U.S. Application Data
(63) Continuation of application No. PCT/KR2025/013025, filed on Aug. 27, 2025.

(30) Foreign Application Priority Data
Oct. 2, 2024 (KR) 10-2024-0134301
Oct. 24, 2024 (KR) 10-2024-0146806

(51) Int. Cl. H05K 5/02; H05K 5/03

(52) U.S. Cl. CPC H05K 5/0226; H05K 5/03

(57) ABSTRACT

A foldable electronic device may comprise: a foldable housing comprising a first housing part and a second housing part, a hinge module comprising a hinge connected to the first housing part and the second housing, and configured to rotatably connect the first housing part and the second housing part about a folding axis positioned between the first housing part and the second housing part, and a display module comprising a display disposed on the first housing part and the second housing part, the display module further includes a flexible display panel, a glass layer disposed on the flexible display, a cover window attached on the glass layer via a first attachment member comprising an adhesive material having a first attaching force in a central area of the display module, and a protective layer disposed adjacent to a side surface of the cover window in an edge area of the display module formed on an outside of the central area and attached on the glass layer via a second attachment member comprising an adhesive material having a second attaching force stronger than the first attaching force.

### CROSS-REFERENCE TO RELATED APPLICATIONS

This application is a continuation of International Application No. PCT/KR2025/013025 designating the United States, filed on Aug. 27, 2025, in the Korean Intellectual Property Receiving Office and claiming priority to Korean Patent Application Nos. 10-2024-0134301, filed on Oct. 2, 2024, and 10-2024-0146806, filed on Oct. 24, 2024, in the Korean Intellectual Property Office, the disclosures of each of which are incorporated by reference herein in their entireties.

### BACKGROUND

### Field

The disclosure relates to a foldable electronic device including a display module, e.g., a display module capable of reduce creasing by preventing or alleviating/reducing plastic deformation caused by tensile and/or compressive stress in the layers forming the display module in a foldable electronic device, and a foldable electronic device including such a display module.

### Description of Related Art

Advancing information communication and semiconductor technologies accelerate the spread and use of various electronic devices. Recent electronic devices are being developed to carry out communication while carried on.

The term “electronic device” may refer, for example, to a device performing a particular function according to its equipped program, such as a home appliance, an electronic scheduler, a portable multimedia player, a mobile communication terminal, a tablet PC, a video/sound device, a desktop PC or laptop computer, a navigation for automobile, etc. For example, the electronic devices may output stored information as voices or images.

As electronic devices are highly integrated, and high-speed, high-volume wireless communication becomes commonplace, an electronic device, such as a mobile communication terminal, is recently being equipped with various functions. For example, an electronic device comes with the integrated functionality, including an entertainment function, such as playing video games, a multimedia function, such as replaying music/videos, a communication and security function, such as for mobile banking, and a scheduling or e-wallet function. These electronic devices have been downsized to be conveniently carried by users.

### SUMMARY

A foldable electronic device according to an example embodiment of the disclosure may comprise: a foldable housing comprising a first housing part and a second housing part, a hinge module including a hinge connected to the first housing part and the second housing part, and configured to rotatably connect the first housing part and the second housing part about a folding axis positioned between the first housing part and the second housing part, and a display module including a display disposed on the first housing part and the second housing part, the display module includes a flexible display panel, a glass layer disposed on the flexible display, a cover window attached on the glass layer via a first attachment member comprising an adhesive material having a first attaching force in a central area of the display module, and a protective layer disposed adjacent to a side surface of the cover window in an edge area of the display module formed on an outside of the central area and attached on the glass layer via a second attachment member comprising an adhesive material having a second attaching force stronger than the first attaching force.

A display module according to an example embodiment of the disclosure may comprise: a flexible display panel, a glass layer disposed on the flexible display, a cover window attached on the glass layer via a first attachment member comprising an adhesive material having a first attaching force in a central area of the display module, and a protective layer disposed adjacent to a side surface of the cover window in an edge area of the display module formed on an outside of the central area and attached on the glass layer via a second attachment member comprising an adhesive material having a second attaching force stronger than the first attaching force.

### BRIEF DESCRIPTION OF THE DRAWINGS

The foregoing and other aspects, configurations, and/or advantages of an embodiment of the disclosure will be more apparent from the following detailed description, taken in conjunction with the accompanying drawings, in which:

FIG. 1 is a block diagram illustrating an example electronic device in a network environment according to an embodiment;

FIG. 2 is a diagram illustrating a front view, side view, and rear view of an example electronic device in an unfolded state according to an embodiment;

FIG. 3 is a diagram illustrating a front view, side view, and rear view illustrating an example electronic device in a folded state according to an embodiment;

FIG. 4 is an exploded perspective view illustrating an electronic device in an unfolded state according to an embodiment;

FIG. 5 is a diagram illustrating a plan view of a foldable electronic device according to an embodiment;

FIG. 6 is a cross-sectional view illustrating a foldable electronic device according to an embodiment;

FIG. 7 is a perspective view illustrating a partial configuration of a display module of a foldable electronic device according to an embodiment;

FIG. 8 is an exploded perspective view illustrating a partial configuration of a display module of a foldable electronic device according to an embodiment;

FIG. 9 is a cross-sectional view illustrating a foldable electronic device according to an embodiment;

FIG. 10 is a cross-sectional view illustrating a foldable electronic device according to an embodiment;

FIGS. 11, 12, 13, 14 and 15 are diagrams illustrating a portion of an example process for manufacturing a display module of a foldable electronic device according to an embodiment;

FIG. 16 is a cross-sectional view illustrating a foldable electronic device according to an embodiment;

FIG. 17 is a cross-sectional view illustrating a foldable electronic device according to an embodiment;

FIG. 18 is a cross-sectional view illustrating a foldable electronic device according to an embodiment;

FIG. 19 is a cross-sectional view illustrating a foldable electronic device according to an embodiment;

FIG. 20 is a cross-sectional view illustrating a foldable electronic device according to an embodiment;

FIG. 21 is a cross-sectional view illustrating a foldable electronic device according to an embodiment;

FIG. 22 is a perspective view illustrating an example foldable electronic device according to an embodiment;

FIG. 23 is a diagram illustrating a side view of a foldable electronic device according to an embodiment;

FIG. 24 is a diagram illustrating a plan view of a foldable electronic device according to an embodiment;

FIG. 25 is a cross-sectional view illustrating a foldable electronic device according to an embodiment;

FIG. 26 is a cross-sectional view illustrating a foldable electronic device according to an embodiment; and

FIG. 27 is a cross-sectional view illustrating a foldable electronic device according to an embodiment.

Throughout the drawings, like reference numerals may be assigned to like parts, components, and/or structures.

### DETAILED DESCRIPTION

The following description taken in conjunction with the accompanying drawings may provide an understanding of various example implementations of the disclosure, including claims and their equivalents. The various example embodiments disclosed in the following description entail various details to aid understanding, but are regarded as examples of various embodiments. Accordingly, it will be understood by those skilled in the art that various changes and modifications may be made to the various implementations described in the disclosure without departing from the scope and spirit of the disclosure. Further, descriptions of well-known functions and configurations may be omitted for clarity and brevity.

The terms and words used in the following description and claims are not limited to the bibliographical meaning, but may be used to clearly and consistently describe an embodiment of the disclosure. Therefore, it will be apparent to those skilled in the art that the following description of various implementations of the disclosure is provided for the purpose of description, not for the purpose of limiting the disclosure including the claims and equivalent thereto.

The singular forms “a,” “an,” and “the” are intended to include the plural forms as well, unless the context clearly indicates otherwise. Thus, as an example, “a component surface” may be interpreted as including one or more of the surfaces of a component.

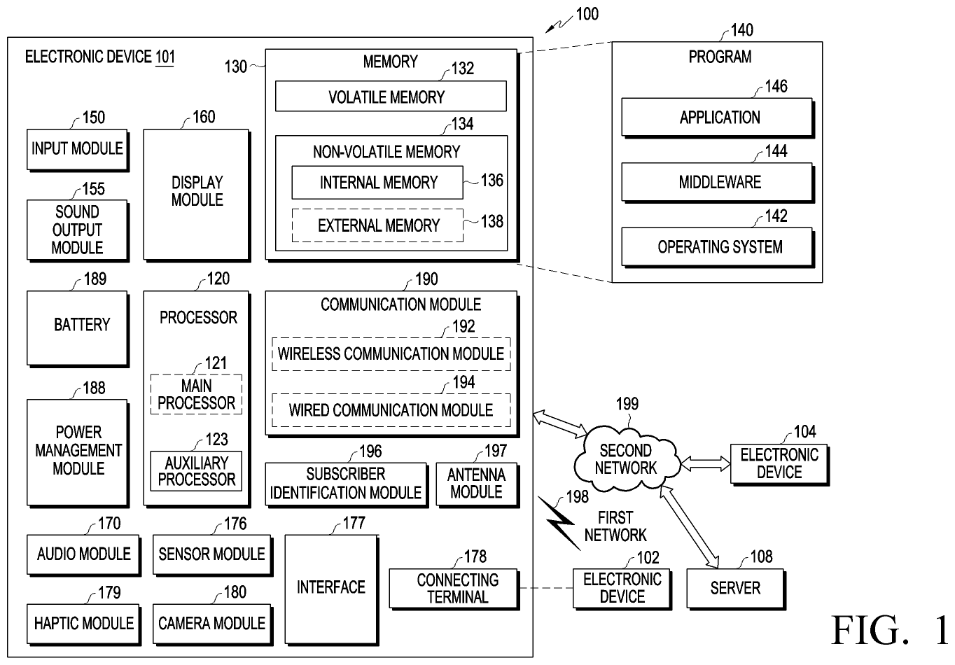

FIG. 1 is a block diagram illustrating an example electronic device 101 in a network environment 100 according to an embodiment.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mm Wave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to an embodiment may be one of various types of electronic devices. The electronic devices may include, for example, a portable communication device (e.g., a smartphone), a computer device, a portable multimedia device, a portable medical device, a camera, a wearable device, a home appliance, or the like. The electronic devices according to an embodiment are not limited to those described above.

It should be appreciated that an embodiment of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to an embodiment, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

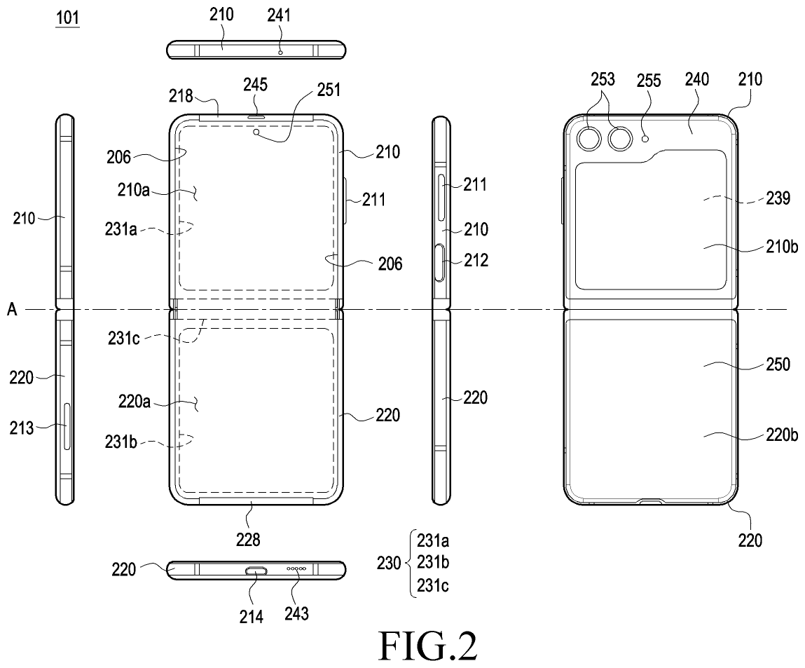

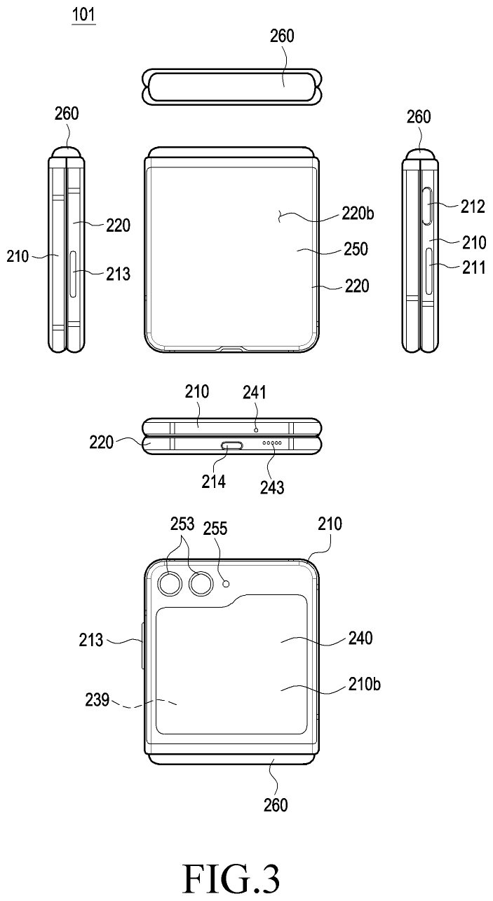

FIG. 2 is a diagram illustrating a front view, side view, and rear view of an example electronic device in an unfolded state according to an embodiment. FIG. 3 is a diagram illustrating a front view, side view, and rear view of an example electronic device in a folded state according to an embodiment.

Referring to FIGS. 2 and 3, an electronic device 101 according to an embodiment may include a first housing 210, a second housing 220, a flexible or foldable display 230 (hereinafter, simply a “first display 230”) (e.g., the display module 160 of FIG. 1) disposed on the first housing 210 and the second housing 220, and a hinge cover 260.

According to an embodiment, the surface on which the first display 230 is disposed may be defined as a front surface of the electronic device 101. At least a portion of the front surface of the electronic device 101 may be formed of a substantially transparent front plate (e.g., a glass plate or polymer plate including various coat layers). The opposite surface of the front surface may be defined as a rear surface of the electronic device 101. The rear surface of the electronic device 101 may be formed by a substantially opaque rear plate (hereinafter, referred to as a ‘back cover’). The back cover may be formed of, e.g., laminated or colored glass, ceramic, polymer, metal (e.g., aluminum, stainless steel (STS), or magnesium), or a combination of at least two thereof. The surface surrounding the space between the front and back surfaces may be defined as a side surface of the electronic device 101. The side surface may be formed by a side bezel structure (or a “side member”) that couples to the front plate and the rear plate and includes a metal and/or polymer. According to an embodiment, the back cover and the side bezel plate may be integrally formed together and include the same material (e.g., a metal, such as aluminum).

According to an embodiment, the electronic device 101 may include at least one or more of a first display 230, audio modules 241, 243, and 245, a sensor module 255, camera devices 251 and 253, key input devices 211, 212, and 213, and a connector hole 214. According to an embodiment, the electronic device 101 may omit at least one (e.g., the key input devices 211, 212, and 213) of the components or additionally include another component (e.g., a light emitting device).

According to an embodiment, the first display 230 may be a display at least a portion of which may be transformed into a flat or curved surface. According to an embodiment, the first display 230 may include a folding area 231c, a first area 231a disposed on one side of the folding area 203 (e.g., an upper side of the folding area 231c of FIG. 2), and a second area 231b disposed on the opposite side of the folding area 231c (e.g., a lower side of the folding area 231c of FIG. 2). However, the segmentation of the first display 230 as shown in FIG. 2 is merely an example, and the first display 230 may be divided into a plurality of (e.g., four or more, or two) areas depending on the structure or function. For example, in the example illustrated in FIG. 2, the first display 230 may be divided into the areas by the folding area 231c or folding axis A but, in an embodiment, the first display 230 may be divided into the areas with respect to another folding area 231c or another folding axis (e.g., a folding axis perpendicular to the folding axis A).

According to an embodiment, the microphone hole 241 may have a microphone inside to obtain external sounds. In an embodiment, there may be a plurality of microphones to be able to detect the direction of a sound.

According to an embodiment, the speaker holes 243 and 245 may include an external speaker hole 243 and a phone receiver hole 245. According to an embodiment, the speaker holes 243 and 245 and the microphone hole 241 may be implemented as a single hole, or speakers may be rested without the speaker holes 243 and 245 (e.g., piezo speakers). Various changes may be made to the position and number of microphone holes 241 and speaker holes 243 and 245 according to an embodiment.

According to an embodiment, the electronic device 101 may include a first camera device 251 disposed on the first surface 210a of the first housing 210 of the electronic device 101 and a second camera device 253 disposed on the second surface 210b. The electronic device 101 may further include a flash (not shown). The camera devices 251 and 253 may include one or more lenses, an image sensor, and/or an image signal processor. The flash (not shown) may include, e.g., a light emitting diode or a xenon lamp.

According to an embodiment, the sensor module 255 may generate an electrical signal or a data value corresponding to an internal operating state of the electronic device 101 or an external environmental state. Although not shown in the drawings, the electronic device 101 may additionally or alternatively include a sensor module (e.g., the sensor module 176 of FIG. 1) other than the sensor module 255 provided on the second surface 210b of the first housing 210. The electronic device 101 may include, as the sensor module, at least one of a proximity sensor, a fingerprint sensor, an HRM sensor, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment, the key input devices 211, 212, and 213 may be disposed on a side surface of the foldable housing (e.g., the hinge cover 260, the first housing 210 and/or the second housing 220). According to an embodiment, the electronic device 101 may exclude all or some of the above-mentioned key input devices 211, 212, and 213 and the excluded key input devices may be implemented in other forms, e.g., as soft keys, on the first display 230. In an embodiment, the key input device may be configured to implement key input by a sensor module (e.g., a gesture sensor).

According to an embodiment, the connector hole 214 may be configured to receive a connector (e.g., a USB connector) for transmitting/receiving power and/or data to/from an external electronic device or, additionally or alternatively, a connector for transmitting/receiving audio signals to/from an external electronic device.

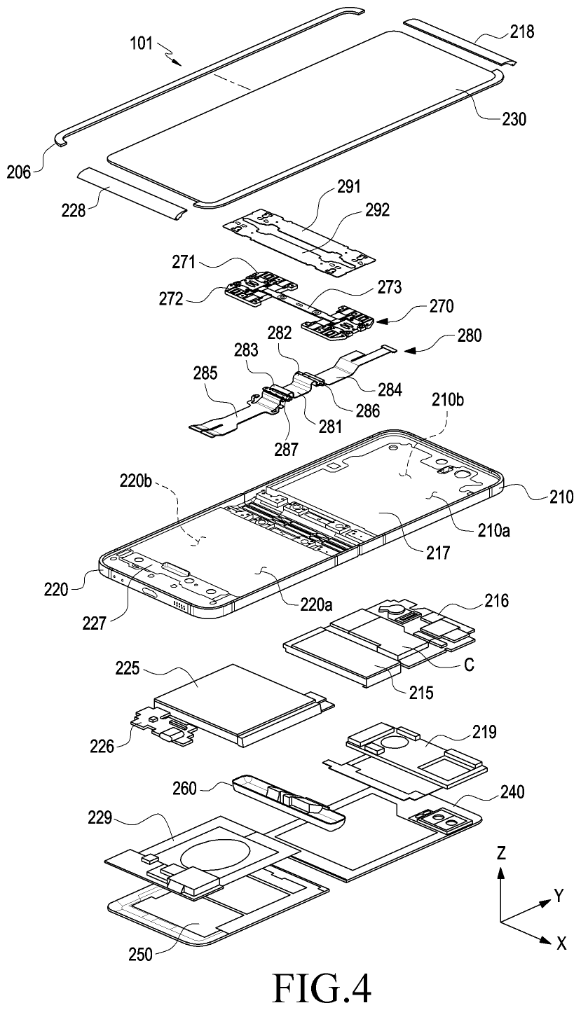

According to an embodiment, a foldable housing may be implemented by a combination of the first housing 210, the second housing 220, the first back cover 240, the second back cover 250, and/or the hinge module (e.g., the hinge structure 270 of FIG. 4). The foldable housing of the electronic device 101 are not limited to the shape and coupling shown but may rather be implemented in other shapes or via a combination and/or coupling of other components. For example, in an embodiment, the first housing 210 and the first rear cover 240 may be integrally formed with each other, and the second housing 220 and the second rear cover 250 may be integrally formed with each other. According to an embodiment of the disclosure, ‘housing’ may refer, for example, to a combination of other various components not mentioned and/or a combined configuration thereof. For example, it may be described that a first area 231a of the first display 230 forms one surface of the first housing 210 and, in an embodiment, the first area 231a of the first display 230 is disposed or attached to one surface of the first housing 210.

According to an embodiment, the first housing 210 may be connected to the hinge structure (e.g., the hinge structure 270 of FIG. 4 described in greater detail below) and may include a first surface 210a facing in a first direction and a second surface 210b facing in a second direction opposite to the first direction. The second housing 220 may be connected to the hinge structure (e.g., the hinge structure 270 of FIG. 4 described in greater detail below) and may include a third surface 220a facing in a third direction and a fourth surface 220b facing in a fourth direction opposite to the third direction and may be rotated or pivoted from the first housing 210 about the hinge structure (or folding axis A).

According to an embodiment, the first housing 210 and the second housing 220 may be disposed on two opposite sides (or upper/lower sides) of the folding axis A. The angle or distance between the first housing 210 and the second housing 220 may be varied depending on whether the electronic device 101 is in the unfolded state, the folded state, or the partially unfolded (or partially folded) intermediate state.

According to an embodiment, the first housing 210 and the second housing 220 may at least partially be formed of a metal or non-metallic material with a rigidity selected to support the first display 230. The at least a portion formed of the metal material may be provided as a ground plane or radiating conductor of the electronic device 101 and, if provided as the ground plane, it may be electrically connected with a ground line formed on the printed circuit board (e.g., the printed circuit board 216 or 226 of FIG. 4).

According to an embodiment, the first rear cover 240 may be disposed on one side (e.g., the upper side in FIG. 2) of the folding axis A, on the rear surface of the electronic device 101, e.g., it may have a substantially rectangular periphery which may be surrounded by the first housing 210 (and/or the side bezel structure). Similarly, the second back cover 250 may be disposed on the opposite side (e.g., the lower side in FIG. 2) of the folding axis A on the rear surface of the electronic device 101 and its periphery may be surrounded by the second housing 220 (and/or the side bezel structure).

According to an embodiment, the first rear cover 240 and the second rear cover 250 may be substantially symmetrical in shape with respect to the folding axis A. However, the first rear cover 240 and the second rear cover 250 are not necessarily symmetrical in shape. In an embodiment, the electronic device 101 may include the first rear cover 240 and the second rear cover 250 in various shapes. In an embodiment, the first rear cover 240 may be integrally formed with the first housing 210, and the second rear cover 250 may be integrally formed with the second housing 220.

According to an embodiment, the first rear cover 240, the second rear cover 250, the first housing 210, and the second housing 220 may form a space where various components (e.g., the printed circuit boards 216 and 226 or batteries 215 and 225 of FIG. 4) of the electronic device 101 may be disposed. According to an embodiment, one or more components may be arranged or visually exposed on/through the rear surface of the electronic device 101. For example, at least a portion of a second display 239 may be visible through the first back cover 240. In an embodiment, one or more components or sensors may be visually exposed through the first back cover 240. According to an embodiment, the components or sensors may include a proximity sensor, a rear camera, and/or a flash. Although not separately shown in the drawings, one or more other components or sensors may be visually exposed through the second back cover 250.

According to an embodiment, the front camera device 251 exposed from the front surface of the electronic device 101 through one or more openings or the rear camera device 253 exposed through the first rear cover 240 may include one or more lenses, an image sensor, and/or an image signal processor. The flash (not shown) may include, e.g., a light emitting diode or a xenon lamp. In an embodiment, two or more lenses (an infrared (IR) camera, a wide-angle lens, and a telephoto lens) and image sensors may be disposed on one surface of the electronic device 101.

According to an embodiment, the foldable housing 210, 220, and 260 may include a hinge cover 260, a first housing 210, and a second housing 220. The first housing 210 and the second housing 220 may be rotated with respect to the hinge structure 270. When the electronic device 101 switches from the unfolded state to the folded state, the first housing 210 and the second housing 220 may rotate with respect to the hinge structure 270 to be close to each other. When the electronic device 101 switches from the folded state to the unfolded state, a portion of the first housing 210 and a portion of the second housing 220 may rotate with respect to the hinge cover 260 so as to move away from each other. According to an embodiment of the disclosure, the folding direction of the first housing 210 and/or the second housing 220 may include a direction in which the first housing 210 and/or the second housing 220 is rotated with respect to the hinge structure 270 when the first housing 210 and/or the second housing 220 is switched from the unfolded state to the folded state. The unfolding direction of the first housing 210 and/or the second housing 220 may include a direction in which the first housing 210 and/or the second housing 220 is rotated with respect to the hinge structure 270 when the first housing 210 and/or the second housing 220 is switched from the folded state to the unfolded state.

According to an embodiment, the electronic device 101 may be changed to a folded state of the first display 230 or an unfolded state of the first display 230. For example, the first housing 210 and the second housing 220 may rotate about the folding axis A between the folded state in which the first area 231a and the second area 231b of the first display 230 face each other and a state (e.g., the unfolded state of the electronic device 101 illustrated in FIG. 2) unfolded from the folded state by a designated angle.

According to an embodiment, as the first housing 210 and the second housing 220 rotate about the folding axis A, the electronic device 101 may include a folded state and an unfolded state. The folded state may be a state in which the first housing 210 and the second housing 220 face each other, and the angle formed by the first housing 210 and the second housing 220 may be less than a predetermined angle (e.g., 10 degrees). The unfolded state may be a state in which the electronic device 101 is fully unfolded or partially unfolded, and an angle formed by the first housing 210 and the second housing 220 may be greater than or equal to the predetermined (e.g., specified) angle.

FIG. 2 illustrates an unfolded state of the electronic device 101 in which the first housing 210 and the second housing 220 form an angle of about 180°. FIG. 3 illustrates the folded state of the electronic device 101 in which the first housing 210 and the second housing 220 face each other and are parallel to each other. In the folded state, the first area 231a and the second area 231b of the first display 230 may be positioned to face each other, and the folding area 231c may be bent.

According to an embodiment, the folding of the electronic device 101 may be implemented in two types: “in-folding” in which the first area 231a and the second area 231b are folded to face each other; and “out-folding” in which the first area 231a and the second area 231b are folded to face in opposite directions. For example, in the in-folding state, the first area 231a and the second area 231b may be substantially concealed, and in the fully unfolded state, the first area 231a and the second area 231b may be disposed to face in substantially the same direction. For example, in the out-folding state, the first area 231a and the second area 231b may be disposed to face in opposite directions to be visible to the outside, and in the fully unfolded state, the first area 231a and the second area 231b may be disposed to face in substantially the same direction.

According to an embodiment, the first display 230 may include a display panel and a window member, and at least a portion of the first display 230 may be formed to be flexible. Although not illustrated separately, it will be easily understood by one of ordinary skill in the art that the first display 230 or the display panel includes various layers such as a light emitting layer, substrate(s) encapsulating the light emitting layer, an electrode or a wiring layer, and/or adhesive layer(s) bonding different adjacent layers. When the first display 230 (e.g., the folding area 231c) is deformed into a flat plate shape and a curved shape, relative displacement may occur between layers of the first display 230. The relative displacement according to the deformation of the first display 230 may increase as it is farther from the folding axis A and/or as the thickness of the first display 230 increases.

According to an embodiment, the window member, e.g., the thin film plate, may serve as a protective film to protect the display panel. As a protective film, the thin film plate may be formed of a material that protects the display panel from external impact, is resistant to scratches, and causes less creases in the folding area 231c even in repetitive folding and unfolding operations of the housings 210 and 220. For example, the material of the thin film plate may include a clear polyimide (CPI) film or ultra-thin glass (UTG).

According to an embodiment, the electronic device 101 may further include protective member(s) 206 or decorative covers(s) 218 and 228 disposed on at least a portion of the edge of the first display 230 on the front surface (e.g., the first surface 210a or the third surface 220a). As an example, the protective member 206 and the decorative covers 218 and 228 may be connected to each other to surround the edge of the first display 230. The protective member 206 or the decorative covers 218 and 228 may prevent or suppress at least a portion of an edge of the first display 230 from contacting a mechanical structure (e.g., the first housing 210 or the second housing 220). The protective member 206 or the decorative covers 218 and 228 may be visually exposed to the outside of the electronic device 101.

According to an embodiment, the decorative covers 218 and 228 and the protective member 206 may be connected to each other. As an example, the decorative covers 218 and 228 and the protective member 206 may be integrally formed. The decorative covers 218 and 228 may extend along the folding axis A. The decorative covers 218 and 228 may include a first decorative cover 218 disposed between a portion of an edge of the first area 231a of the first display 230 and an inner wall of the first housing 210. The decorative covers 218 and 228 may include a second decorative cover 228 disposed between a portion of an edge of the second area 231b of the first display 230 and an inner wall of the second housing 220. As an example, the first decorative cover 218 and the second decorative cover 228 may extend substantially side by side along the folding axis A.

According to an embodiment, the speaker hole 245 may be formed in the decorative cover 218 or the protective member 206 interposed between the edge of the first area 231a of the first display 230 and the inner wall of the first housing 210. As an example, the speaker hole 245 may be formed in the first decorative cover 218.

FIG. 4 is an exploded perspective view illustrating an example electronic device 101 according to an embodiment.

Referring to FIG. 4, according to an embodiment of the disclosure, the first display 230 may be visible through a significant portion of the front surface of the electronic device 101. In an embodiment, the shape of the first display 230 may be formed to be substantially the same as the shape of the periphery of the front surface of the electronic device 101.

In FIG. 4, ‘Y’ may refer, for example, to a length direction of the electronic device 101 in the second state. Further, in an embodiment of the disclosure, ‘+Y’ may refer, for example, to the upward direction of the electronic device 101 around the folding axis A of the electronic device 101, and ‘−Y’ may refer, for example, to the downward direction of the electronic device 101 around the folding axis A of the electronic device 101.

According to an embodiment, the foldable housing of the electronic device 101 may include the first housing 210 and the second housing 220. According to an embodiment, the first housing 210 may include a first surface 210a and a second surface 210b facing in a direction opposite to the first surface 210a. The second housing 220 may include a third surface 220a and a fourth surface 220b facing in a direction opposite to the third surface 220a. The electronic device 101 or the foldable housing 210, 220, 260 may additionally or alternatively include a bracket assembly 217, 227. The bracket assembly 217, 227 may include a first bracket assembly 217 disposed in the first housing 210 and a second bracket assembly 227 disposed in the second housing 220. At least a portion of the bracket assembly 217, 227, e.g., at least a portion of the first bracket assembly 217 and at least a portion of the second bracket assembly 227, may serve as a plate for supporting the hinge structure 270.

According to an embodiment, various electric components may be disposed on the printed circuit board 216, 226. For example, a processor (e.g., the processor 120 of FIG. 1), memory (e.g., the memory 130 of FIG. 1), and/or an interface (e.g., the interface 177 of FIG. 1) may be mounted on the printed circuit board 216, 226. The processor may include one or more of, e.g., a central processing unit, an application processor, a graphic processing device, an image signal processing, a sensor hub processor, or a communication processor. The memory may include, e.g., a volatile or non-volatile memory. The interface may include, e.g., a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to an embodiment, the printed circuit boards 216, 226 may include a first printed circuit board 216 disposed on the side of the first bracket assembly 217 and a second printed circuit board 226 disposed on the side of the second bracket assembly 227. The first printed circuit board 216 and the second printed circuit board 226 may be disposed inside the space formed by the foldable housing 210, 220, 260, the bracket assembly 217, 227, the first rear cover 240 and/or the second rear cover 250. Components for implementing various functions of the electronic device 101 may be disposed on the first printed circuit board 216 and the second printed circuit board 226. For example, a processor may be disposed on the first printed circuit board 216, and an audio interface may be disposed on the second printed circuit board 226.

According to an embodiment, batteries 215, 225 may be disposed adjacent to the printed circuit board 216, 226 to supply power to the electronic device 101. At least a portion of the batteries 215, 225 may be disposed on substantially the same plane as the printed circuit board 216 or 226. According to an embodiment, a first battery 215 may be disposed adjacent to the first printed circuit board 216, and a second battery 225 may be disposed adjacent to the second printed circuit board 226. The batteries 215, 225 may be a device for supplying power to at least one component of the electronic device 101. The battery 189 may include, e.g., a primary cell which is not rechargeable, a secondary cell which is rechargeable, or a fuel cell. The batteries 215, 225 may be integrally or detachably disposed inside the foldable housing 210, 220, 260.

According to an embodiment, the hinge structure 270 may be a component to provide a folding axis (e.g., the folding axis A of FIG. 2) and rotatably connect or couple the foldable housing 210, 220, 260 and/or the bracket assembly 217, 227. The hinge structure 270 may include a first hinge structure 271 disposed on the side of the first printed circuit board 216 and a second hinge structure 272 disposed on the side of the second printed circuit board 226. The hinge structure 270 may be disposed between the first printed circuit board 216 and the second printed circuit board 226. According to an embodiment, the hinge structure 270 may be formed substantially integrally with at least a portion of the first bracket assembly 217 and at least a portion of the second bracket assembly 227.

In an embodiment, the hinge structure 270 may include a center bar 273. The center bar 273 may be disposed between the first hinge structure 271 and the second hinge structure 272. The center bar 273 may be connected to the first hinge structure 271 and the second hinge structure 272. The center bar 273 may be raised or lowered during the process in which the electronic device 101 changes between an unfolded state (e.g., the state of FIG. 2) and a folded state (e.g., the state of FIG. 3). The center bar 273 may support the first display 230.

According to an embodiment, the electronic device 101 may include a first hinge plate 291 and a second hinge plate 292. The first hinge plate 291 and the second hinge plate 292 may be disposed on the hinge structure 270. The first hinge plate 291 and the second hinge plate 292 may be positioned between the first display 230 and the hinge structure 270. The first hinge plate 291 may be disposed on the side of the first housing 210. The second hinge plate 292 may be disposed on the side of the second housing 220. The first hinge plate 292 and the second hinge plate 292 may support the first display 230. The first hinge plate 291 and the second hinge plate 292 may be components of a ‘hinge plate assembly’. For example, the hinge plate assembly may include the first hinge plate 291 and the second hinge plate 292.

According to an embodiment, a ‘housing structure’ may include the foldable housing 210, 220, 260 and may denote one resultant from assembling and/or combining at least one component disposed in the foldable housing 210, 220, 260. The housing structure may include a first housing structure and a second housing structure. For example, a component assembled to include at least one component among the first housing 210 and the first bracket assembly 217, the first printed circuit board 216, and the first battery 215 disposed inside the first housing 210 may be referred to as the ‘first housing structure.’ As another example, a component assembled to include at least one component among the second housing 220 and the second bracket assembly 227, the second printed circuit board 226, and the second battery 225 disposed inside the second housing 220 may be referred to as the ‘second housing structure.’ However, it should be noted that the ‘first housing structure and the second housing structure’ are not limited to the addition of the above-described components, but may add or omit various other components.

According to an embodiment, the flexible connection member 280 may be, e.g., a flexible printed circuit board (FPCB). The flexible connection member 280 may connect various electrical elements disposed on the first printed circuit board 216 and the second printed circuit board 226. To this end, the flexible connection member 280 may be disposed to cross the ‘first housing structure’ and the ‘second housing structure’. According to an embodiment, the flexible connection member 280 may be disposed to cross at least a portion of the hinge structure 270. According to an embodiment, the flexible connection member 280 may be configured to connect the flexible printed circuit board 216 and the second printed circuit board 226 across the hinge structure 270 along a direction parallel to, e.g., the y axis of FIG. 4. For example, the flexible connection member 280 may include a central portion 281 disposed on one side (e.g., an upper side) of the hinge cover 260. For example, the flexible connection member 280 may include a hinge cover 260 and a first curved portion 282 disposed on one side (e.g., an upper side) of the first bracket assembly 217. For example, the flexible connection member 280 may include a hinge cover 260 and a second curved portion 283 disposed on one side (e.g., an upper side) of the second bracket assembly 227. The first curved portion 282 and the second curved portion 283 may have a shape convex toward one side (e.g., an upper side) when the electronic device 101 is in the unfolded state (e.g., the state of FIG. 2). For example, the flexible connection member 280 may include a first extension 284 that is connected to the first curved portion 282, passes through the first housing 210 (e.g., the first bracket assembly 217), and extends from the other side (e.g., a lower side) of the first housing 210 (e.g., the first bracket assembly 217). For example, the flexible connection member 280 may include a second extension 285 that is connected to the second curved portion 283, passes through the second housing 220 (e.g., the second bracket assembly 227), and extends from the other side (e.g., a lower side) of the second housing 220 (e.g., the second bracket assembly 227). A space (hereinafter, referred to as a ‘wiring space’) surrounded by at least a portion of the first hinge structure 271, at least a portion of the second hinge structure 272, and at least a portion of the hinge cover 260 may be formed in a position adjacent to the first hinge structure 271 and the second hinge structure 272. According to an embodiment, at least a portion 281, 282, 283 of the flexible connection member 280 may be disposed in the wiring space.

According to an embodiment, the electronic device 101 may include a first holder assembly 286 and a second holder assembly 287. The first holder assembly 286 and the second holder assembly 287 may be disposed on one side (e.g., an upper side) of the flexible connection member 280. The first holder assembly 286 may be fixed to the first housing 210 (e.g., the first bracket assembly 217), and the second holder assembly 287 may be fixed to the second housing 220 (e.g., the second bracket assembly 227). The first holder assembly 286 and the second holder assembly 287 may fix the flexible connection member 280 to the first housing 210 and the second housing 220, respectively.

According to an embodiment, the hinge cover 260 may be a component that covers at least a portion of the hinge structure 270 or the wiring space. In an embodiment, the hinge cover 260, together with the hinge structure 270, may form the wiring space and protect components (e.g., at least a portion 283 of the flexible connection member 280) disposed in the wiring space from external impact. According to an embodiment, the hinge cover 260 may be disposed between the first housing 210 and the second housing 220. In the electronic device 101 which is of an in-folding type, the hinge cover 260 may be at least partially concealed by the foldable housing 210, 220, 260. For example, in the folded state, the hinge cover 260 may be visually exposed to the external space between the rear surface (e.g., the first back cover 240) of the first housing 210 and the back cover (e.g., the second back cover 250) of the second housing 220 and, in the unfolded state, the hinge cover 360 may be substantially received inside the first housing 210 or the second housing 220 to be visually concealed.

According to an embodiment, the antenna module 219, 229 (e.g., the antenna module 197 of FIG. 1) may be disposed between the rear cover 240, 250 and the batteries 215, 225. According to an embodiment, the antenna module 219, 229 may include a first antenna module 219 disposed on the side of the first housing 210 and a second antenna module 229 disposed on the side of the second housing 220. The antenna module 219, 229 may include, e.g., a near field communication (NFC) antenna, a wireless charging antenna, and/or a magnetic secure transmission (MST) antenna, performing short-range communication with an external device or wirelessly transmitting/receiving power required for charging. In an embodiment, an antenna structure may be formed by a portion or combination of the side bezel structure of the foldable housing 210, 220, 260 and/or bracket assembly.

According to an embodiment, the rear cover 240, 250 may include a first rear cover 240 and a second rear cover 250. The rear cover 240, 250 may be combined with the foldable housing 210, 220, 260 to protect the above-described components (e.g., the printed circuit board 216, 226, the batteries 215, 225, the flexible connection member 280, or the antenna module 219, 229) disposed in the foldable housing 210, 220, 260. As described above, the rear cover 240, 250 may be formed substantially integrally with the foldable housing 210, 220, 260.

According to an embodiment, the protective member 206 and/or the decorative covers 218 and 228 may protect at least a portion of the edge of the first display 230. The protective member 206 may be disposed between the edge of the first area 231a (see FIG. 2) of the first display 230 and the inner wall of the first housing 210 and/or between the edge of the second area 231b (see FIG. 2) of the first display 230 and the inner wall of the second housing 220 to prevent or block the edge of the first display 230 from directly contacting the inner walls of the housings 210 and 220.

In the disclosure, a type of electronic device that is folded (e.g., folded up and down) with respect to the horizontally extended folding axis F is described, but the disclosure is not limited thereto, and the contents of the disclosure described below may be applied equally and/or similarly to various types of foldable electronic devices. For example, the contents of the disclosure described below may be applied equally and/or similarly to a type of electronic device (e.g., a ‘fold’ type of foldable electronic device) that is folded (e.g., folded left and right) with respect to a vertically extended folding axis or a type of electronic device (e.g., a multi-foldable electronic device) that includes multiple folding axes. For example, if the folding axis of each type of foldable electronic device corresponds to the ‘folding axis’ of the content described below, the details described in the disclosure below may be applied equally and/or similarly to each type of foldable electronic device.

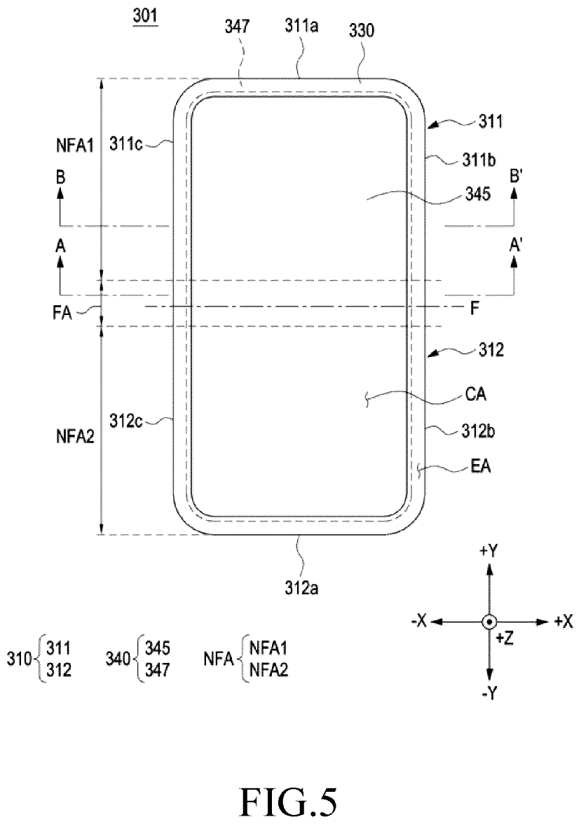

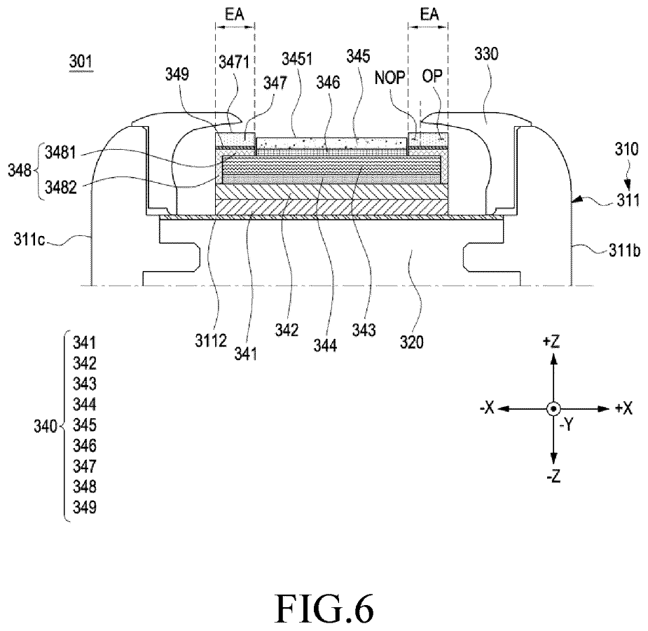

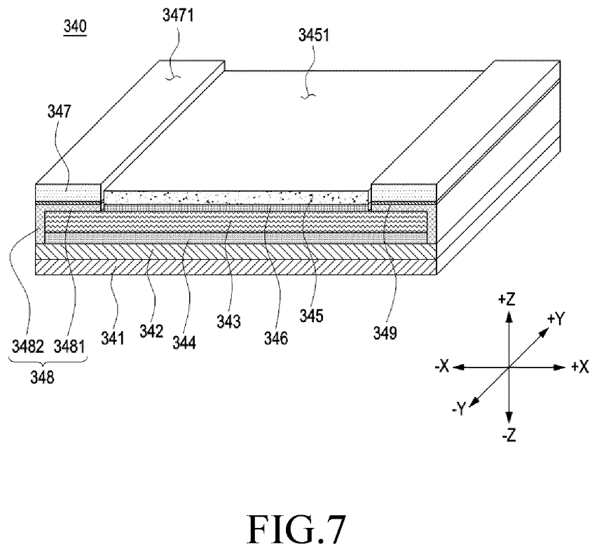

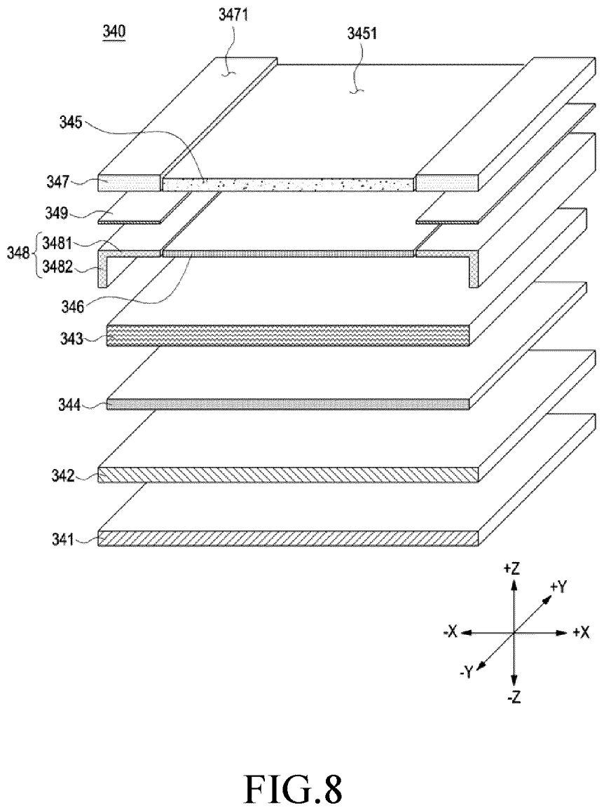

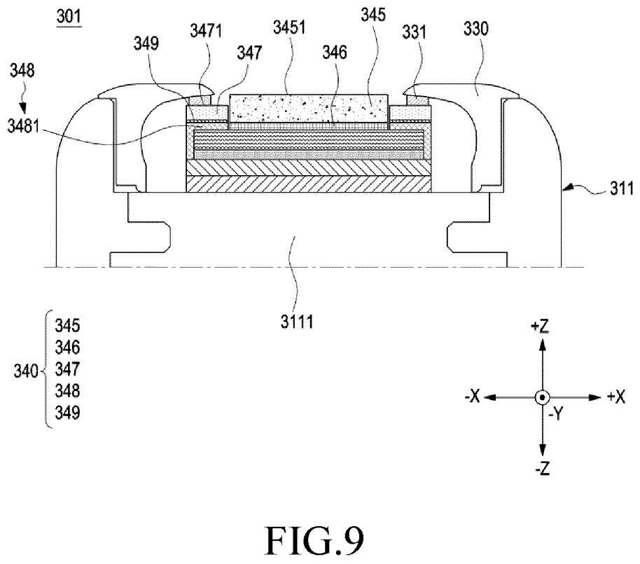

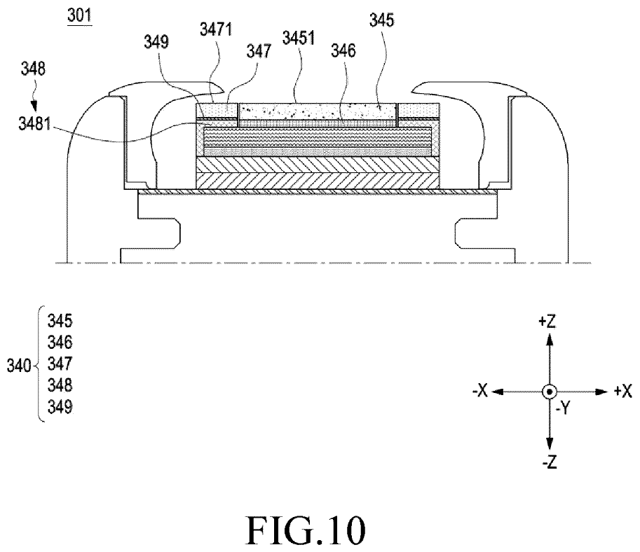

FIG. 5 is a diagram illustrating a plan view of a foldable electronic device according to an embodiment. FIG. 6 is a cross-sectional view illustrating a foldable electronic device according to an embodiment. FIG. 7 is a perspective cross-sectional view illustrating a partial configuration of a display module of a foldable electronic device according to an embodiment. FIG. 8 is an exploded perspective view illustrating a partial configuration of a display module of a foldable electronic device according to an embodiment. FIG. 9 is a cross-sectional view illustrating a foldable electronic device according to an embodiment. FIG. 10 is a cross-sectional view illustrating a foldable electronic device according to an embodiment.

For example, FIG. 5 is a plan view illustrating a display module 340 in an unfolded state (e.g., the state of FIG. 2) of a foldable electronic device. FIG. 6 is a cross-sectional view taken along line A-A′ of FIG. 5. FIG. 7 is a perspective view illustrating a portion (e.g., the folding area FA portion) of the display module 340. FIG. 8 is an exploded perspective view of FIG. 7. FIG. 9 is a cross-sectional view taken along line B-B′ of FIG. 5. FIG. 10 is a cross-sectional view illustrating an example of the display module 340. The cross-sectional structure of the non-conductive member 330 and/or the display module 340, in the cross-sectional structure taken along a direction (e.g., the third lateral direction (+Y axis) and/or the fourth lateral direction (−Y direction)) perpendicular to line A-A′, may be identical or similar to the cross-sectional structure of the non-conductive member 330 and the display module 340 illustrated in FIG. 6 and/or FIG. 9.

The detailed configuration of the foldable electronic device 301 according to an example embodiment of the disclosure not described below may be the same as the detailed configuration of the electronic device 101 according to an embodiment of the disclosure described with reference to FIGS. 1, 2, 3 and 4.

Hereinafter, the foldable electronic device 301 of the disclosure may include a foldable housing 301, a non-conductive member 330, and a display module 340, but some thereof may be omitted, or additional components may be included.

Hereinafter, the display module 340 according to an embodiment of the disclosure may include a flexible display panel 342, a glass layer 343, a cover window 345, a first attachment member 346, a protective layer 347, and a second attachment member 348, but some thereof may be omitted, or additional components may be included.

Hereinafter, the ‘first lateral direction’ may refer, for example, to a direction parallel to the folding axis F, and may refer, for example, to the +X direction which is the right direction in FIG. 5. The ‘second lateral direction’ is a direction opposite to the first lateral direction (+X direction), and may refer, for example, to the −X direction, which is the left direction in FIG. 5. The ‘third lateral direction’ is a lateral direction crossing the first lateral direction (+X direction) and/or the second lateral direction (−X direction) and may refer, for example, to the +Y direction which is the upward direction in FIG. 5. The ‘fourth lateral direction’ is a direction opposite to the third lateral direction (+Y direction), and may refer, for example, to the −Y direction, which is the downward direction in FIG. 5.

Hereinafter, the ‘first thickness direction’ is the direction of one thickness of the foldable housing 310 and/or the display module 340, and may refer, for example, to the +Z direction, which is the upward direction in FIGS. 5 and 6. The ‘second thickness direction’ is a direction opposite to the first thickness direction (+Z direction), and may refer, for example, to the −Z direction which is the downward direction in FIGS. 5 and 6. The thickness direction’ may refer, for example, to the first thickness direction (+Z direction) and/or the second thickness direction (−Z direction).

According to an embodiment, the foldable electronic device 301 may include a foldable housing 310. The foldable housing 310 may include a first housing part 311 (e.g., the first housing 210 of FIGS. 2 and 3) and a second housing part 312 (e.g., the second housing 220 of FIGS. 2 and 3). The first housing part 311 and the second housing part 312 may rotate with respect to the folding axis F.

According to an embodiment, the first housing part 311 may include a first outer surface 311a, a second outer surface 311b, and a third outer surface 311c. The first outer surface 311a may be substantially parallel to the folding axis F. The first outer surface 311a may be an edge facing away from the folding axis F of the first housing part 311. For example, the first outer surface 311a may be an edge facing a third lateral direction (+Y direction) of the first housing part 311. The second outer surface 311b may be substantially perpendicular to the first outer surface 311a (or the folding axis F). The second outer surface 311b may be an edge facing the first lateral direction (+X direction) of the first housing part 311. The third outer surface 311c may be substantially perpendicular to the first outer surface 311a (or the folding axis F). The third outer surface 311c may be substantially parallel to the second outer surface 311b. The third outer surface 311c may face the second outer surface 311b. The third outer surface 311c may be an edge facing the second lateral direction (−X direction) of the first housing part 311.

According to an embodiment, the second housing part 312 may include a fourth outer surface 312a, a fifth outer surface 312b, and a sixth outer surface 312c. The fourth outer surface 312a may be substantially parallel to the folding axis F. The fourth outer surface 312a may be an edge facing away from the folding axis F of the second housing part 312. For example, the fourth outer surface 312a may be an edge facing the fourth lateral direction (−Y direction) of the second housing part 312. The fifth outer surface 312b may be substantially perpendicular to the fourth outer surface 312a (or the folding axis F). The fifth outer surface 312b may be an edge of the second housing part 312 toward the first lateral direction (+X direction). The sixth outer surface 312c may be substantially perpendicular to the fourth outer surface 312a (or the folding axis F). The sixth outer surface 312c may be substantially parallel to the fifth outer surface 312b. The sixth outer surface 312c may face the fifth outer surface 312b. The sixth outer surface 312c may be an edge facing the second lateral direction (−X direction) of the second housing part 312.

According to an embodiment, referring to FIG. 6, the foldable electronic device 301 may include a hinge module 320 (e.g., the hinge structure 270 of FIG. 4). The hinge module 320 may be connected between the first housing part 311 and the second housing part 312. The hinge module 320 may rotatably couple the first housing part 311 and the second housing part 312 with respect to the folding axis F positioned between the first housing part 311 and the second housing part 312.

According to an embodiment, the foldable electronic device 301 may include a first hinge plate 3112 (e.g., the first hinge plate 291 of FIG. 4). The first hinge plate 3112 may be disposed on a side of the first housing part 311. The first hinge plate 3112 may be adjacent to the folding axis F. The first hinge plate 3112 may be disposed on the hinge module 320. The first hinge plate 3112 may support the display module 340. The first hinge plate 3112 may be adjacent to the rigidity reinforcing layer 341 of the display module 340.

According to an embodiment, the foldable electronic device 301 may include a second hinge plate (not illustrated) (e.g., the second hinge plate 292 of FIG. 4). The second hinge plate may be disposed on the side of the second housing part 312. The second hinge plate may be adjacent to the folding axis F. The second hinge plate may be disposed on the hinge module 320. The second hinge plate may support the display module 340. The second hinge plate may be adjacent to the rigidity reinforcing layer 341 of the display module 340.

According to an embodiment, the foldable electronic device 301 may include a non-conductive member 330 (e.g., the protective member 206 of FIGS. 2 and 4 and the decorative covers 218 and 228). The non-conductive member 330 may be disposed along the edge of the foldable housing 310. For example, the non-conductive member 330 may be disposed along the first outer surface 311a, the second outer surface 311b, and/or the third outer surface 311c of the first housing part 311. For example, the non-conductive member 330 may be disposed along the fourth outer surface 312a, the fifth outer surface 312b, and/or the sixth outer surface 312c of the second housing part 312. The non-conductive member 330 may be configured to cover an edge portion of the display module 340. The non-conductive member 330 may be disposed on an edge of the display module 340. For example, at least a portion of the non-conductive member 330 may be disposed above the edge of the display module 340 (on the side in the first thickness direction (+Z direction)). The non-conductive member 330 may partially overlap the display module 340 (e.g., the flexible display panel 342, the second attachment member 348, and/or the protective layer 347) in the thickness direction (e.g., the first thickness direction (+Z direction) and/or the second thickness direction (−Z direction)).

According to an embodiment, the non-conductive member 330 may include a ‘deco member’ capable of protecting at least a portion of an edge of the display module 340. For example, in FIG. 9 illustrating a cross section of the non-folding area NFA, a portion referred to as the non-conductive member 330 may be a “deco member”. The non-conductive member 330 may be referred to as a ‘deco member’, a ‘decorative member’, and/or a ‘protective member’. According to an embodiment, the non-conductive member 330 may include a ‘dust cover’ that prevents/reduces foreign objects such as dust from flowing between the display module 340 and the housing 310. For example, in FIG. 6, which illustrates a cross section of the folding area FA, a portion referred to as the non-conductive member 330 may be a “dust cover”. The non-conductive member 330 may be referred to as a “dust cover” and/or a “cover member”.

According to an embodiment, referring to FIG. 9, the foldable electronic device 301 may include a blocking member 331. The blocking member 331 may be disposed between the protective layer 347 and a non-conductive member (e.g., a decor member). The blocking member 331 may be disposed on the protective layer 347 (e.g., on the side in the first thickness direction (+Z direction) of the protective layer 347). The blocking member 331 may be disposed in an area overlapping the non-conductive member 330 in the first thickness direction (+Z direction) and/or the second thickness direction (−Z direction). For example, the blocking member 331 may be formed in a range in which it does not protrude from the non-conductive member 330 and may not be visually exposed from the outside. The blocking member 331 may be an elastic body. For example, the blocking member 331 may include a sponge material or an elastomer (e.g., rubber). The blocking member 331 may prevent/reduce foreign objects from flowing between the display module 340 and the non-conductive member 330. The blocking member 331 may be referred to as a ‘foreign object prevention sheet’.

According to an embodiment, the foldable electronic device 301 may include a display module 340 (e.g., the first display 230 of FIG. 4). The display module 340 may be disposed on the first housing part 311 and the second housing part 312. For example, the display module 340 may be disposed on the first supporting member 3111 of the first housing part 311 (e.g., the first bracket assembly 217 of FIG. 4) and the second supporting member of the second housing part 312 (e.g., the second bracket assembly 227 of FIG. 4). The display module 340 may be disposed and/or attached to a surface of the first housing part 311 and the second housing part 312 facing the first thickness direction (+Z direction). The display module 340 may be referred to as a ‘flexible display module’.

According to an embodiment, the display module 340 may be disposed to at least partially overlap the non-conductive member 330 in the thickness direction (e.g., the first thickness direction (+Z direction) and/or the second thickness direction (−Z direction)) of the foldable housing 310. For example, the display module 340 may be disposed under at least a portion of the non-conductive member 330 (e.g., on the side in the second thickness direction (−Z direction)).

According to an embodiment, the display module 340 may include a folding area FA (e.g., the folding area 231c of FIG. 2). The folding area FA may be formed in an area adjacent to the folding axis F. The folding area FA may extend in parallel to the folding axis F. The folding area FA may be bent when the foldable electronic device 301 is switched from an unfolded state (e.g., the state of FIG. 2) to a folded state (e.g., the state of FIG. 3).

According to an embodiment, the display module 340 may include a non-folding area NFA (e.g., the first area 231a of FIG. 2 and the second area 231b of FIG. 2). The non-folding area NFA may be formed on a side far from the folding axis F with respect to the folding area FA. For example, the non-folding area NFA may include a first non-folding area NFA1 formed on the side in the third lateral direction (+Y direction) of the folding area FA. The first non-folding area NFA1 may be an area overlapping the first housing part 311. The first non-folding area NFA1 may be a portion that is supported by a first supporting member (e.g., the first bracket assembly 217 of FIG. 4) of the first housing part 311 and does not bend. For example, the non-folding area NFA may include a second non-folding area NFA2 formed on the side in the fourth lateral direction (−Y direction) of the folding area FA. The second non-folding area NFA2 may be a portion overlapping the second housing part 312. The second non-folding area NFA2 may be a portion that is supported by a second supporting member (e.g., the second bracket assembly 227 of FIG. 4) of the second housing part 312 and does not bend.

According to an embodiment, the display module 340 may include a central area CA. The central area CA may refer, for example, to an inner area of the edge area EA when the display module 340 is viewed from the front (e.g., when the display module 340 is viewed in the first thickness direction (+Z direction)). The central area CA may be the area that does not overlap the non-conductive member 330 in the thickness direction (e.g., the first thickness direction (+Z direction) and/or the second thickness direction (−Z direction)).

According to an embodiment, the display module 340 may include an edge area EA. The edge area EA may be an outer area of the central area CA of the display module 340. For example, the edge area EA may be an area formed along at least a portion of the edge of the display module 340. For example, the edge area EA may be an area adjacent to the outermost side of the display module 340. The edge area EA may at least partially overlap the non-conductive member 330 in the thickness direction (e.g., the first thickness direction (+Z direction) and/or the second thickness direction (−Z direction)).

According to an embodiment, the display module 340 may include a rigidity reinforcing layer 341. The rigidity reinforcing layer 341 may include a lower structure of the display module 340. The rigidity reinforcing layer 341 may be disposed on the first housing part 311, the second housing part 312, the first hinge plate 3112, and/or the second hinge plate. For example, in the folding area FA, the rigidity reinforcing layer 341 may be adjacent to the first hinge plate 3112 (e.g., the first hinge plate 291 of FIG. 4) and the second hinge plate (e.g., the second hinge plate 292 of FIG. 4). For example, in the non-folding area NFA, the rigidity reinforcing layer 341 may be adjacent to the first supporting member 3111 (e.g., the first bracket assembly 217 of FIG. 4) of the first housing part 311 and the second supporting member (e.g., the second bracket assembly 227 of FIG. 4) of the second housing part 312. The rigidity reinforcing layer 341 may include various layers including a metal plate, a film, a lattice, and/or an attachment member (e.g., an adhesive layer) that bonds different layers.

According to an embodiment, the display module 340 may include a flexible display panel 342. The flexible display panel 342 may be disposed on the rigidity reinforcing layer 341. For example, the flexible display panel 342 may be stacked on the side in the direction of the first thickness (+Z direction) of the rigidity reinforcing layer 341. The flexible display panel 342 may include various layers including an emission layer, an encapsulating substrate for encapsulating the emission layer, an electrode or line layer, a film, and/or an attachment member (e.g., an adhesive layer) for bonding different adjacent layers. The flexible display panel 342 may output a screen.

According to an embodiment, the display module 340 may include a glass layer 343. The glass layer 343 may be disposed (or stacked) on the flexible display panel 342. For example, the glass layer 343 may be disposed (or stacked) on the side of the flexible display panel 342 in the first thickness direction (+Z direction). The glass layer 343 may cover at least a portion of the flexible display panel 342. The glass layer 343 may protect the flexible display panel 342 from external impact. The glass layer 343 may be referred to as a ‘foldable thin glass (FTG)’ and/or ‘ultra-thin glass (UTG), a ‘thin plate’, a ‘window’ and/or a ‘window member’.

According to an embodiment, the glass layer 343 may be disposed in an area overlapping the flexible display panel 342. For example, the glass layer 343 may have an area smaller than that of the flexible display panel 342.

According to an embodiment, the display module 340 may include a glass layer attachment member 344. The glass layer 343 may be attached onto the flexible display panel 342 through a glass layer attachment member 344. For example, the glass layer attachment member 344 may include a pressure sensitive adhesive (PSA). In an embodiment, the glass layer attachment member 344 may include an optical transparent adhesive. For example, the glass layer attachment member 344 may include an optical transparent resin (OCR).

According to an embodiment, the display module 340 may include a cover window 345. The cover window 345 may be disposed (or stacked) on the glass layer 343. For example, the cover window 345 may be disposed on the side in the direction of the first thickness (+Z direction) of the glass layer 343. The cover window 345 may protect the glass layer 343 and/or the flexible display panel 342 from external impact. The cover window 345 may prevent/reduce by-products from scattering when the glass layer 343 is damaged.

According to an embodiment, the cover window 345 may be detachably attached to the glass layer 343. For example, the cover window 345 may be replaceable. The cover window 345 may be understood as a protective film that may be directly replaced by the user.

According to an embodiment, the cover window 345 may be attached onto the glass layer 343 in the central area CA of the display module 340. The cover window 345 may be disposed inside the protective layer 347. For example, the cover window 345 may be disposed in an area that does not overlap the non-conductive member 330. Accordingly, in the process of replacing the cover window 345, the cover window 345 may be easily replaced without interfering with the non-conductive member 330.

According to an embodiment, referring to FIG. 6, in the folding area FA, the upper surface 3451 of the cover window 345 may be formed at a position recessed from the upper surface 3471 of the protective layer 347. For example, in the folding area FA, the surface 3451 facing the first thickness direction (+Z direction) of the cover window 345 may be formed at a lower position than the surface 3471 facing the first thickness direction (+Z direction) of the protective layer 347. For example, in the folding area FA, the sum of the thicknesses of the cover window 345 and the first attachment member 346 in the thickness direction (e.g., the first thickness direction (+Z direction)) and/or the second thickness direction (−Z direction)) may be smaller than the sum of the thicknesses of the protective layer 347 and the first portion 3481 of the second attachment member 348 and the masking part 349 in the thickness direction (e.g., the first thickness direction (+Z direction) and/or the second thickness direction (−Z direction)). Accordingly, since the tensile stress and/or compressive stress acting on the cover window 345 may be decreased during the folding and unfolding process of the foldable electronic device 301, the creasing in the folding area FA caused by plastic deformation of the cover window 345 may be mitigated.

In an embodiment, referring to FIG. 10, in the folding area FA, an upper surface 3451 (e.g., a surface facing the first thickness direction (+Z direction)) of the cover window 345 may be formed at a height corresponding to an upper surface 3471 (e.g., a surface facing the first thickness direction (+Z direction)) of the protective layer 347. For example, in the folding area FA, the sum of the thicknesses of the cover window 345 and the first attachment member 346 in the thickness direction (e.g., the first thickness direction (+Z direction) and/or the second thickness direction (−Z direction)) may correspond to the sum of the thicknesses of the protective layer 347 and the first portion 3481 of the second attachment member 348 and the masking part 349 in the thickness direction (e.g., the first thickness direction (+Z direction) and/or the second thickness direction (−Z direction)). For example, it may be understood that no step is formed between the upper surface 3451 of the cover window 345 and the upper surface 3471 of the protective layer 347.

According to an embodiment, referring to FIG. 9, a portion of an edge of the cover window 345 may protrude above the protective layer 347. For example, in at least a portion of the non-folding area NFA, the edge of the cover window 345 may be formed at a higher position than the surface 3471 facing the first thickness direction (+Z direction) of the protective layer 347. For example, a step where the cover window 345 is higher may be formed between the edge of the cover window 345 and the protective layer 347. Therefore, when attaching and detaching the cover window 345, the user may easily lift the edge of it, making replacement much simpler. In an embodiment, a portion of the edge of the cover window 345 may protrude above the protective layer 347 in the folding area FA.

According to an embodiment, referring to FIG. 9, in at least a portion of the non-folding area NFA, the upper surface 3451 of the cover window 345 may be formed at a position protruding from the upper surface 3471 of the protective layer 347. For example, in the non-folding area NFA, the surface 3451 facing the first thickness direction (+Z direction) of the cover window 345 may be formed at a higher position than the surface 3471 facing the first thickness direction (+Z direction) of the protective layer 347. For example, in the non-folding area NFA, the sum of the thicknesses of the cover window 345 and the first attachment member 346 in the thickness direction (e.g., the first thickness direction (+Z direction) and/or the second thickness direction (−Z direction)) may be larger than the sum of the thicknesses of the protective layer 347 and the first portion 3481 of the second attachment member 348 and the masking part 349 in the thickness direction (e.g., the first thickness direction (+Z direction) and/or the second thickness direction (−Z direction)). The thickness of the cover window 345 in the non-folding area NFA in the thickness direction (e.g., the first thickness direction (+Z direction) and/or the second thickness direction (−Z direction)) may be larger than the thickness of the cover window 345 in the folding area FA in the thickness direction (e.g., the first thickness direction (+Z direction) and/or the second thickness direction (−Z direction)). The cover window 345 in the non-folding area NFA and the cover window 345 in the folding area FA may be seamlessly connected without leaving a step therebetween. Enhancing the durability of the display module 340 may be achieved by increasing the thickness of the cover window 345 in the non-folding area NFA where creases are less likely to occur.

In an embodiment, referring to FIG. 10, in the non-folding area NFA, the upper surface 3451 (e.g., the surface facing the first thickness direction (+Z direction) of the cover window 345 may be formed at the height corresponding to the upper surface 3471 (e.g., the surface facing the first thickness direction (+Z direction) of the protective layer 347. For example, in the non-folding area NFA, the sum of the thicknesses of the cover window 345 and the first attachment member 346 in the thickness direction (e.g., the first thickness direction (+Z direction) and/or the second thickness direction (−Z direction)) may correspond to the sum of the thicknesses of the protective layer 347 and the first portion 3481 of the second attachment member 348 and the masking part 349 in the thickness direction (e.g., the first thickness direction (+Z direction) and/or the second thickness direction (−Z direction)). For example, it may be understood that no step is formed between the upper surface 3451 of the cover window 345 and the upper surface 3471 of the protective layer 347.

According to an embodiment, the display module 340 may include a first attachment member 346. The first attachment member 346 may be disposed between the cover window 345 and the glass layer 343. The cover window 345 may be attached to the glass layer 343 through the first attachment member 346.

According to an embodiment, the first attachment member 346 may include various types of adhesives. For example, the first attachment member 346 may include a pressure-sensitive adhesive PSA. In an embodiment, the first attachment member 346 may include an optical transparent adhesive (e.g., an optical transparent resin (OCR)).

According to an embodiment, the first attachment member 346 may have a first attaching force. The first attaching force may be weaker than the second attaching force of the second attachment member 348. Accordingly, in the process of detaching the cover window 345 from the glass layer 343, the protective layer 347 is not detached, and the cover window 345 may be easily detached.

According to an embodiment, the display module 340 may include a protective layer 347. The protective layer 347 may be disposed (or stacked) on the glass layer 343. For example, the protective layer 347 may be disposed on the side of the glass layer 343 in the direction of the first thickness (+Z direction). The protective layer 347 may protect an edge portion of the glass layer 343 and/or the flexible display panel 342 from an external impact. The protective layer 347 may prevent/reduce by-products from scattering when the glass layer 343 is damaged.

According to an embodiment, the protective layer 347 may be attached onto the glass layer 343 in the edge area EA of the display module 340. The protective layer 347 may at least partially overlap the non-conductive member 330 in the thickness direction (e.g., the first thickness direction (+Z direction) and/or the second thickness direction (−Z direction)). For example, the protective layer 347 may include an overlapping portion OP. The overlapping portion OP may be an area overlapping the non-conductive member 330 in the thickness direction (e.g., the first thickness direction (+Z direction) and/or the second thickness direction (−Z direction)). For example, the protective layer 347 may include a non-overlapping portion NOP. The non-overlapping portion NOP may not overlap the non-conductive member 330 in the thickness direction (e.g., the first thickness direction (+Z direction) and/or the second thickness direction (−Z direction)). The non-overlapping portion NOP may be formed inside the overlapping portion OP.

According to an embodiment, the outline of the protective layer 347 may be disposed outside the outline of the glass layer 343. For example, the edge of the glass layer 343 may be disposed at a position overlapping the protective layer 347 in the thickness direction (e.g., the first thickness direction (+Z direction) and/or the second thickness direction (−Z direction)). For example, it may be understood that the protective layer 347 covers the edge of the glass layer 343 in the thickness direction (e.g., the first thickness direction (+Z direction) and/or the second thickness direction (−Z direction)). Accordingly, the protective layer 347 may effectively protect the glass layer 343 from external impact and effectively prevent/reduce by-products of the damaged glass layer 343 from scattering.

According to an embodiment, the protective layer 347 may be disposed to implement a non-stacked structure for preventing/reducing plastic deformation of the display module 340. For example, the protective layer 347 may be disposed in an outer area (e.g., an edge area EA) of the cover window 345. The protective layer 347 may be disposed adjacent to a side surface of the cover window 345. For example, it may be understood that the cover window 345 and the protective layer 347 are disposed in different areas not to be stacked on each other. The thickness of the display module 340 may be reduced using a protective layer 347 and cover window 345 that are not stacked, which in turn reduces the stress on the display module 340 when folding the foldable electronic device 301. This helps prevent/suppress the display module 340 from becoming plastically deformed to cause creases. Further, the creases on the display module 340 can be prevented/reduced from getting worse due to the differences in the degree of plastic deformation between the layers that may occur during the folding or unfolding of the foldable electronic device 301 if the cover window 345 and protective layer 347 are stacked.

Table 1 below shows the experimental results comparing the creases and the stress acting on the structure (structure 1) in which the protective layer 347 and the cover window 345 are simply stacked and the structure (structure 2) in which the protective layer 347 and the cover window 345 are not stacked like the display module 340 according to an embodiment of the disclosure.

TABLE 1

| | | | structure 2 | |
|---|---|---|---|---|
| | | | protective layer | cover window |
| | structure 1 | | 347 portion | 345 portion |
| stress | 18.4 | MPa | 10.9 MPa | 7.2 MPa |
| stress relaxation rate of | | | 40.8% | 60.9& |
| structure 2 to structure 1 | | | | |

| | | | |
|---|---|---|---|
| size of crease in display | 149.3 | um | 113.2 um |
| module 340 | | | |

Referring to Table 1, in structure 1, it may be identified that the stress acting on the display module 340 is 18.4 MPa. It may be identified that in structure 2, the stress on the protective layer 347 of the display module 340 is 10.9 Mpa, a decrease of 40.8% compared to structure 1, while the stress on the cover window 345 is 7.2 Mpa, a decrease of 60.9% compared to structure 1. Due to the differences in stress acting on structures 1 and 2, it may be identified that in structure 1, the size of the creases of the display module 340 (e.g., the distance between the peak and the valley of the crease) is 149.3 um, while in structure 2, the size of the creases of the display module 340 is decreased to 113.2 um.

According to an embodiment, the display module 340 may include a second attachment member 348. At least a portion of the second attachment member 348 may be disposed between the protective layer 347 and the glass layer 343. The protective layer 347 may be attached to the edge area EA of the glass layer 343 through the second attachment member 348. The second attachment member 348 may protect an edge portion of the glass layer 343 from an external impact. The second attachment member 348 may prevent/reduce by-products from scattering when the glass layer 343 is damaged.

According to an embodiment, the second attachment member 348 may include various types of adhesives. For example, the second attachment member 348 may include an optical transparent adhesive. The optically transparent adhesive may include an optically transparent resin (OCR). In an embodiment, the second attachment member 348 may include a pressure-sensitive adhesive PSA.

According to an embodiment, the second attachment member 348 may have a second attaching force. The second attaching force may be stronger than the first attaching force of the first attachment member 346. Accordingly, it is possible to prevent or inhibit the protective layer 347 from being delaminated from the glass layer 343 in the process of replacing the cover window 345.

According to an embodiment, the second attachment member 348 may be configured to cover at least a portion of the upper surface (e.g., the surface facing the first thickness direction (+Z direction) of the edge portion of the glass layer 343 and at least the portion of the side surface of the glass layer 343 (e.g., the surface facing the first lateral direction (+X direction), the second lateral direction (−X direction), the third lateral direction (+Y direction), and/or the fourth lateral direction (−Y direction)). For example, the second attachment member 348 may include a first portion 3481. The first portion 3481 may be configured to cover a portion of the upper surface of the glass layer 343. For example, the second attachment member 348 may include a second portion 3482. The second portion 3482 may be configured to cover at least a portion of the side surface of the glass layer 343. As such, through the structure in which the second attachment member 348 covers the side surface of the glass layer 343, the outermost portion of the glass layer 343 may be protected from external impact, and by-products may be prevented/reduced from being scattered when the outermost portion of the glass layer 343 is damaged.

According to an embodiment, the display module 340 may include a masking part 349. At least a portion of the masking part 349 may be disposed between the protective layer 347 and the second attachment member 348. For example, the masking part 349 may be disposed between the protective layer 347 and the second attachment member 348 (e.g., the first portion 3481 of the second attachment member 348). The masking part 349 may be formed by being printed on a lower surface (e.g., a surface facing the second thickness direction (−Z direction)) of the protective layer 347. In an embodiment, the masking part 349 may be provided as a separate film for blocking the passage of light and attached to the lower surface of the protective layer 347 (e.g., the surface facing the second thickness direction (−Z direction)) and/or the upper surface of the second attachment member 348 (e.g., the surface facing the first thickness direction (+Z direction)). The masking part 349 may enhance appearance quality by covering the line structure formed at the edge of the display module 340 or the edges of the layers of the display module 340, and may prevent and/or reduce light leakage that may occur along the edge of the display module 340. The masking part 349 may be referred to as a ‘masking layer’.

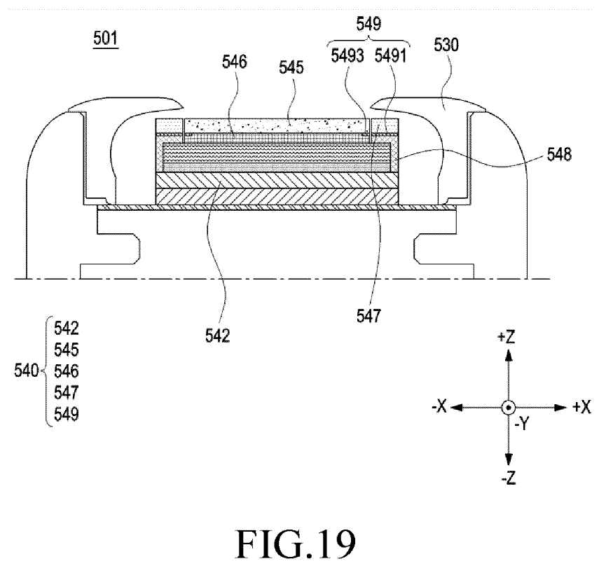

In an embodiment (not illustrated), the masking part 349 may be extended or contracted according to elements to be covered under the masking part 349. For example, the masking part 349 may be formed only in a portion of an area between the protective layer 347 and the second attachment member 348. For example, the masking part 349 may further include a portion disposed between the cover window 345 and the first attachment member 346. For example, the masking part 349 may include a first masking part disposed between the protective layer 347 and the second attachment member 348, and a third masking part disposed between the cover window 345 and the first attachment member 346. In this case, in order to prevent and/or reduce light from leaking from the flexible display panel 342 between the first masking part and the third masking part, the flexible display panel 342 may be configured not to emit light or to emit light of a color corresponding to the masking part 349 in an area corresponding to the gap formed between the first masking part and the third masking part. Such a structure may be understood to be similar to the structure of the foldable electronic device 501 and/or the display module 540 according to an embodiment of the disclosure to be described in greater detail below with reference to FIG. 19.

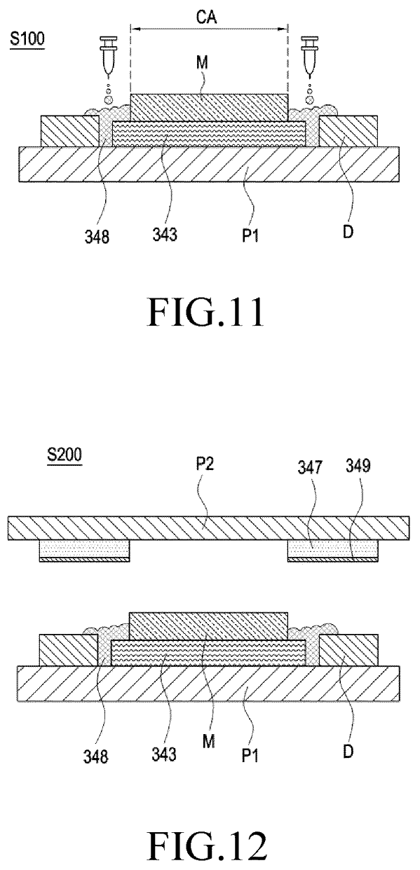

FIGS. 11, 12, 13, 14 and 15 are diagrams illustrating a portion of an example process for manufacturing a display module of a foldable electronic device according to an embodiment.

Hereinafter, an example manufacturing process of a display module 340 according to an embodiment of the disclosure is described with reference to FIGS. 11, 12, 13, 14 and 15 (which may be referred to as FIGS. 11 to 15).

Referring to FIG. 11, a method for manufacturing a display module according to an embodiment may include an operation of seating the glass layer 343 on the first plate P1. The first plate P1 may be understood as a member serving as a palette for manufacturing the display module 340. The glass layer 343 may be disposed between the dam members D disposed on the first plate P1. The dam member D may prevent and/or reduce the second attachment member 348 in a liquid state from being spread outward. A masking member M may be disposed on the glass layer 343. The masking member M may have a size corresponding to the central area CA. For example, the masking member M may be disposed in an area corresponding to the central area CA.

Referring to FIG. 11, a method for manufacturing a display module according to an embodiment may include an operation S100 of providing a second attachment member 348. The second attachment member 348 may be provided in a liquid state. The second attachment member 348 may be provided between the glass layer 343 and the dam member D. For example, the second attachment member 348 may fill the space between the glass layer 343 and the dam member D. When the second attachment member 348 in a liquid state fills the space between the glass layer 343 and the dam member D, a portion of the second attachment member 348 may overflow onto the glass layer 343. The attachment member 348 on the glass layer 343 may not encroach on the central area CA due to the presence of masking member M. The masking member M may be understood as guiding a position where the second attachment member 348 is to be provided on the glass layer 343.

Referring to FIG. 12, a method for manufacturing a display module according to an embodiment may include an operation S200 of providing a protective layer 347. The protective layer 347 may be provided on an edge area of the glass layer 343, and on the dam member D and the second attachment member 348. For example, the protective layer 347 may be provided in an outer space of the masking member M. The protective layer 347 may be provided in a state of being attached to the second plate P2. The second plate P2 may be referred to as a ‘molding plate’. The masking part 349 may be provided together with the protective layer 347 in a state of being pre-printed on one surface (e.g., the lower surface) of the protective layer 347.

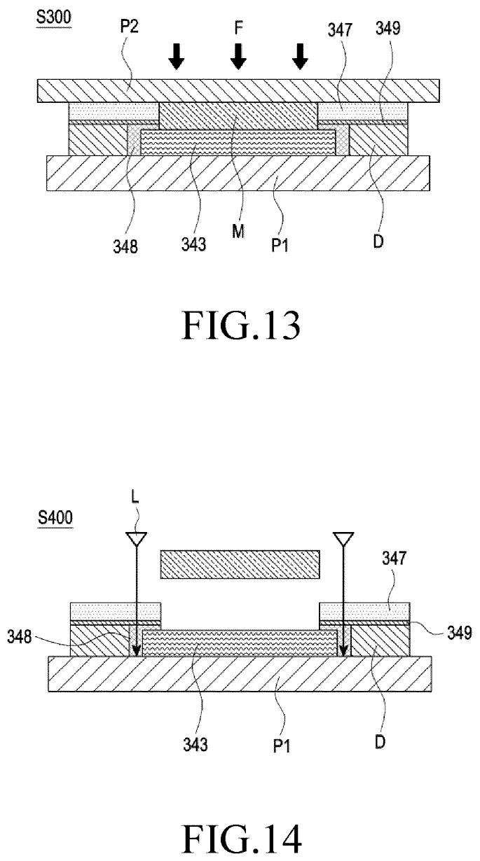

Referring to FIG. 13, the method for manufacturing a display module according to an embodiment may include an operation S300 of pressing the second plate P2 toward the first plate P1. As the second plate P2 is pressed (e.g., by applying pressure force F), the second attachment member 348 in a liquid state may be planarized. The curing operation of the second attachment member 348 may be performed while the second plate P2 is pressed. The curing operation of the second attachment member 348 may be performed by irradiating ultraviolet (UV) rays to the second attachment member 348 or performing heat treatment.

Referring to FIG. 14, a method for manufacturing a display module according to an embodiment may include an operation S400 of trimming the second attachment member 348, the protective layer 347, and the masking part 349. The trimming operation S400 may be performed after the second attachment member 348 is cured. The trimming operation S400 may be performed along the outermost line of the protective layer 347, the masking part 349, and the second attachment member 348 of the final display module (e.g., the display module 340 of FIG. 6). The trimming operation S400 may be performed by irradiating the laser beam L. The laser beam L may penetrate the protective layer 347, the masking part 349, and the second attachment member 348. In an embodiment, the trimming operation S400 may be performed through a mechanical method (e.g., CNC processing).

Referring to FIG. 14, a method for manufacturing a display module according to an embodiment may include an operation of removing the masking member M. The masking member M may be removed before the trimming operation S400 or after the trimming operation S400.

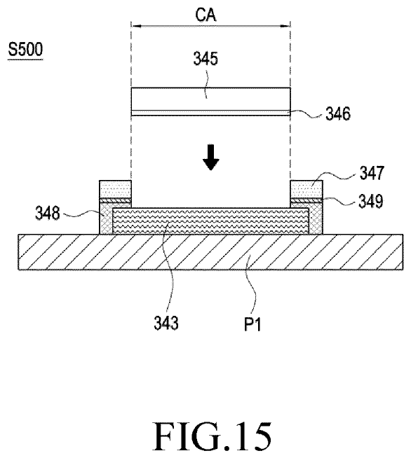

Referring to FIG. 15, a method for manufacturing a display module according to an embodiment may include an operation S500 of providing a cover window 345. The cover window 345 may be provided on the glass layer 343. The cover window 345 may be provided in the central area CA. For example, the cover window 345 may be provided in an area between the protective layers 347. The cover window 345 may be attached onto the glass layer 343. The cover window 345 may be attached onto the glass layer 343 through the first attachment member 346. The first attachment member 346 may be provided together with the cover window 345 in a state of being attached to one surface (e.g., the lower surface) of the cover window 345.

The method for manufacturing the display module according to an embodiment may include the operation (not illustrated) of detaching the assembly (hereinafter, a glass assembly) including the glass layer 343, the protective layer 347, the cover window 345, the first attachment member 346, and the second attachment member 348 from the first plate P1 and attaching the same on the flexible display panel (e.g., the flexible display panel 342 of FIG. 6). The glass assembly may be attached to the flexible display panel (e.g., the flexible display panel 342 of FIG. 6) through the glass layer attachment member (e.g., the glass layer attachment member of FIG. 6).

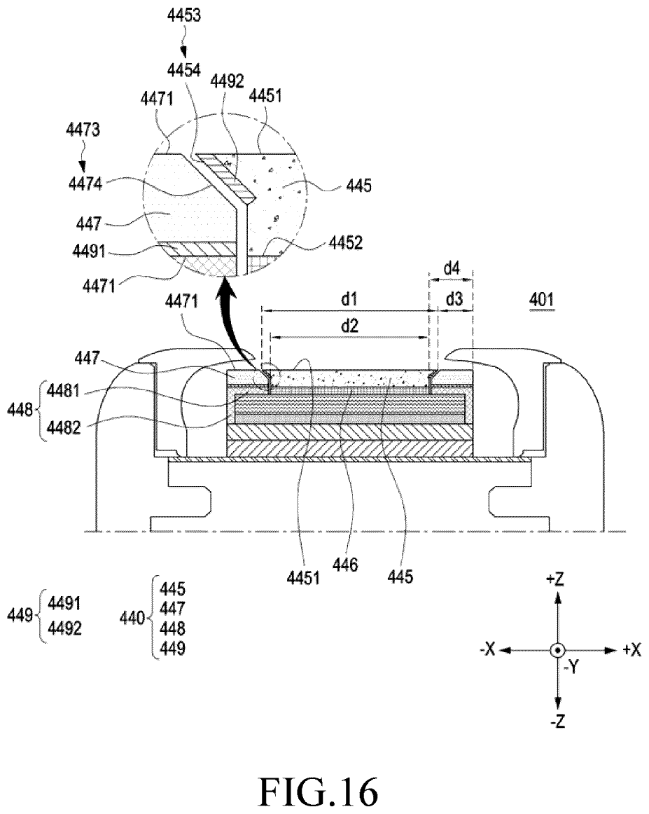

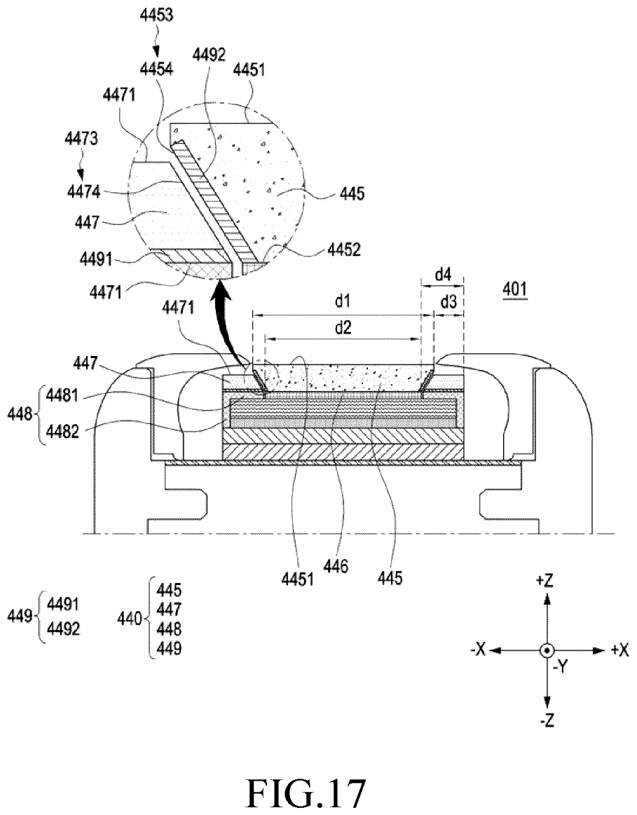

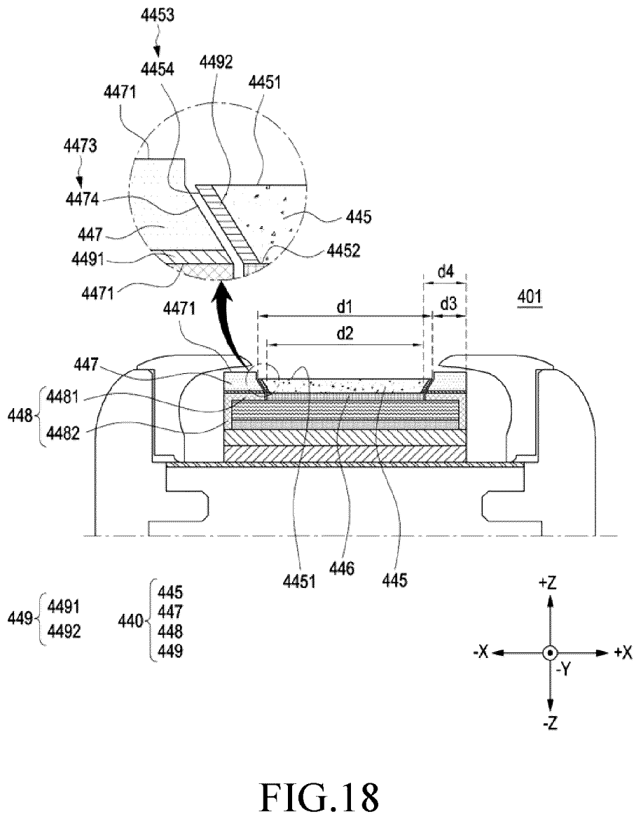

FIG. 16 is a cross-sectional view illustrating an example foldable electronic device according to an embodiment. FIG. 17 is a cross-sectional view illustrating an example foldable electronic device according to an embodiment. FIG. 18 is a cross-sectional view illustrating an example foldable electronic device according to an embodiment.

For example, FIG. 16 is a cross-sectional view taken along line A-A′ of FIG. 5. FIG. 17 is a cross-sectional view taken along line B-B′ of FIG. 5. FIG. 18 is a cross-sectional view illustrating an example of the display module 340.

The detailed configuration of the foldable electronic device 401 according to an embodiment of the disclosure, which is not described below, may be identical or similar to the detailed configuration of the electronic device 101 according to an embodiment of the disclosure described with reference to FIGS. 1, 2, 3 and 4 and/or the detailed configuration of the foldable electronic device 301 according to an embodiment of the disclosure described with reference to FIGS. 5 to 15.

The detailed configuration of the display module 440 according to an embodiment of the disclosure, which is not described below, may be identical or similar to the detailed configuration of the display module 160 according to an embodiment of the disclosure described with reference to FIG. 1, the detailed configuration of the first display 230 according to an embodiment of the disclosure described with reference to FIGS. 2, 3 and 4, and/or the detailed configuration of the display module 340 according to an embodiment of the disclosure described with reference to FIGS. 5 to 15.

According to an embodiment, the outer surface 4453 of the cover window 445 may include a first inclined surface 4454. The first inclined surface 4454 may be inclined so that the width of the cover window 445 increases in the first thickness direction (+Z direction) in the cross-sectional view of the display module 440. For example, in the cross-sectional view of the display module 440, the first inclined surface 4454 may be inclined so that the upper surface 4451 (e.g., the surface facing the first thickness direction (+Z direction)) has a first width d1 and the lower surface 4452 (e.g., the surface facing the second thickness direction (−Z direction)) has a second width d2 smaller than the first width d1. For example, through the first inclined surface 4454, the width between the upper end of the first inclined surface 4454 (e.g., the end facing the first thickness direction (+Z direction)) may be the first width d1, and the width between the lower end of the first inclined surface 4454 (e.g., the end facing the second thickness direction (−Z direction)) may have the second width d2 smaller than the first width (d1).

According to an embodiment, the first inclined surface 4454 may form a portion of the outer surface 4453 of the cover window 445. The first inclined surface 4454 may be formed on at least a portion of the outer surface 4453 of the cover window 445 facing the inner surface 447 of the protective layer 447. Referring to FIG. 16, in the folding area (e.g., the folding area FA of FIG. 5), the first inclined surface 4454 may be formed in the upper area (e.g., the area facing the first thickness direction (+Z direction)) of the outer surface 4453 of the cover window 445, and the lower area (e.g., the area facing the second thickness direction (−Z direction)) of the outer surface 4453 of the cover window 445 may be formed in parallel to the thickness direction (e.g., the first thickness direction (+Z direction) and/or the second thickness direction (−Z direction)). Referring to FIG. 17, in the non-folding area (e.g., the non-folding area NFA of FIG. 5), the first inclined surface 4454 may be formed in the lower area (e.g., the area facing the second thickness direction (−Z direction)) of the outer surface 4453 of the cover window 445, and the upper area (e.g., the area facing the first thickness direction (+Z direction)) of the outer surface 4453 of the cover window 445 may be formed in parallel to the thickness direction (e.g., the first thickness direction (+Z direction) and/or the second thickness direction (−Z direction)). In an embodiment (not illustrated), the first inclined surface 4454 may be formed over the entire outer surface 4453 of the cover window 445.

According to an embodiment, a side surface 4473 (e.g., the inner surface 4473) facing the cover window 445 of the protective layer 447 may include a second inclined surface 4474. The second inclined surface 4474 may be inclined substantially corresponding to the first inclined surface 4454. For example, the second inclined surface 4474 may be inclined so that the width of the protective layer 447 increases in the first thickness direction (+Z direction) in the cross-sectional view of the display module 440. For example, in the cross-sectional view of the display module 440, the second inclined surface 447 may be inclined so that the upper surface 4471 (e.g., the surface facing the first thickness direction (+Z direction)) has a third width d3 and the lower surface 4472 (e.g., the surface facing the second thickness direction (−Z direction)) has a fourth width d4 larger than the third width d3. For example, through the second inclined surface 4474, the width of the upper end of the second inclined surface 4474 (e.g., the end facing the first thickness direction (+Z direction)) may be the third width d3, and the width of the lower end of the second inclined surface 4474 (e.g., the end facing the second thickness direction (−Z direction)) may be the fourth width d4 larger than the third width d3. The second inclined surface 4474 may be formed at a position corresponding to the first inclined surface 4454. The first inclined surface 4454 and the second inclined surface 4474 may face each other.

According to an embodiment, the second inclined surface 4474 may form a portion of the inner side surface 4473 of the protective layer 447. The second inclined surface 4474 may be formed on at least a portion of the inner surface 4473 of the protective layer 447 facing the outer surface 4453 of the cover window 445. Referring to FIG. 16, in the folding area (e.g., the folding area FA of FIG. 5), the second inclined surface 4474 may be formed in the upper area (e.g., the area facing the first thickness direction (+Z direction)) of the inner surface 4473 of the protective layer 447, and the lower area (e.g., the area facing the second thickness direction (−Z direction)) of the inner surface 447 of the protective layer 447 may be formed in parallel in the thickness direction (e.g., the first thickness direction (+Z direction) and/or the second thickness direction (−Z direction)). Referring to FIG. 17, in the non-folding area (e.g., the non-folding area NFA of FIG. 5), the second inclined surface 4474 is formed in the lower area (e.g., the area facing the second thickness direction (−Z direction)) of the inner surface 4473 of the protective layer 447, and the upper area (e.g., the area facing the first thickness direction (+Z direction)) of the inner surface 447 of the protective layer 447 may be formed in parallel with the thickness direction (e.g., the first thickness direction (+Z direction) and/or the second thickness direction (−Z direction)). In an embodiment (not illustrated), the second inclined surface 4474 may be formed over the entire inner surface 4473 of the protective layer 447.

According to an embodiment, the masking part 449 may include a first masking part 4491. The first masking part 4491 may be disposed between the protective layer 447 and the second attachment member 448.

According to an embodiment, the masking part 449 may include a second masking part 4492. The second masking part 4492 may be disposed between the cover window 445 and the protective layer 447. The second masking part 4492 may include a portion inclined to substantially correspond to the first inclined surface 4454. For example, the second masking part 4492 may be formed between the first inclined surface 4454 and the second inclined surface 4474. For example, the second masking part 4492 may be understood to be formed on at least an inclined portion of the boundary between the outer surface 4453 of the cover window 445 and the inner surface 447 of the protective layer 447. In an embodiment, as illustrated in FIG. 16, the first masking part 4491 and the second masking part 4492 may be spaced apart from each other. In an embodiment, as illustrated in FIG. 17, the first masking part 4491 and the second masking part 4492 may be connected to each other. For example, the second masking part 4492 may extend from the first masking part 4491 to a space between the cover window 445 and the protective layer 447.

In an embodiment, the visibility of the step between the cover window 445 and the protective layer 447 may be mitigated by the oblique structure between the cover window 445 and the protective layer 447 formed by the first inclined surface 4454 and the second inclined surface 4474 and the second masking part 4492 formed by the oblique structure. For example, when the display module 440 is viewed in the first thickness direction (+Z direction), the boundary between the cover window 445 and the protective layer 447 may not be visible, so the quality of appearance may be enhanced, and light leakage to the boundary between the cover window 445 and the protective layer 447 may be prevented or alleviated.

In an embodiment, the user may easily peel off the edge portion of the cover window 445 when removing the cover window 445 using the oblique structure formed by the first inclined surface 4454 and the second inclined surface 4474. This may lead to easier replacement of the cover window 445.

According to an embodiment, referring to FIG. 16, an upper surface 4451 (e.g., a surface facing the first thickness direction (+Z direction)) of the cover window 445 in the folding area FA may be formed at a height corresponding to an upper surface 4471 (e.g., a surface facing the first thickness direction (+Z direction)) of the protective layer 447. For example, in the folding area FA, the sum of the thicknesses of the cover window 445 and the first attachment member 446 in the thickness direction (e.g., the first thickness direction (+Z direction) and/or the second thickness direction (−Z direction)) may correspond to the sum of the thicknesses of the protective layer 447 and the first portion 4481 and the first masking part 4491 in the thickness direction (e.g., the first thickness direction (+Z direction) and/or the second thickness direction (−Z direction)). For example, it may be understood that a step is not formed between the upper surface of the cover window 445 and the upper surface of the protective layer 447.

In an embodiment, referring to FIG. 18, in the folding area (e.g., the folding area FA of FIG. 5), the upper surface 4451 of the cover window 445 may be formed at a position recessed more than the upper surface 4471 of the protective layer 447. For example, in the folding area (e.g., the folding area FA of FIG. 5), the surface 4451 of the cover window 445 in the first thickness direction (+Z direction) may be formed at a lower position than the surface 4471 in the first thickness direction (+Z direction) of the protective layer 447. For example, in the folding area (e.g., the folding area FA of FIG. 5), the sum of the thicknesses of the cover window 445 and the first attachment member 446 in the thickness direction (e.g., the first thickness direction (+Z direction) and/or the second thickness direction (−Z direction)) may be smaller than the sum of the thicknesses of the protective layer 447 and the first portion 4481 of the first attachment member 448 and the first masking part 4491 in the thickness direction (e.g., the first thickness direction (+Z direction) and/or the second thickness direction (−Z direction)).

According to an embodiment, referring to FIG. 17, in at least a portion of the non-folding area (e.g., the non-folding area NFA of FIG. 5), the upper surface 4451 of the cover window 445 may be formed at a position protruding from the upper surface 4471 of the protective layer 447. For example, in the non-folding area (e.g., the non-folding area (NFA of FIG. 5), the surface 4451 of the cover window 445 facing the first thickness direction (+Z direction)) may be formed at a higher position than the surface 4471 facing the first thickness direction (+Z direction)) of the protective layer 447. For example, in the non-folding area (e.g., the non-folding area (NFA of FIG. 5), the sum of the thicknesses of the cover window 445 and the first attachment member 446 in the thickness direction (e.g., the first thickness direction (+Z direction) and/or the second thickness direction (−Z direction)) may be larger than the thicknesses of the protective layer 447 and the first portion 4481 of the second attachment member 448 and the first masking part 441 in the thickness direction (e.g., the first thickness direction (+Z direction) and/or the second thickness direction (−Z direction)). The cover window 445 in the non-folding area (e.g., the non-folding area NFA of FIG. 5) and the cover window 445 in the folding area (e.g., the folding area FA of FIG. 5) may be seamlessly connected without leaving a step therebetween. By increasing the cover window 445 in a non-folding area (e.g., the non-folding area NFA of FIG. 5) that is less likely to cause creases, durability of the display module 440 may be enhanced.

In an embodiment, as illustrated in FIG. 16 illustrating a cross section of a folding area (e.g., the folding area FA of FIG. 5), in a non-folding area (e.g., the surface facing the first thickness direction (+Z direction)) of the cover window 445 may be formed at a height corresponding to the upper surface 4471 (e.g., the surface facing the first thickness direction (+Z direction)) of the protective layer 447. For example, in the non-folding area (e.g., the non-folding area (NFA of FIG. 5), the sum of the thicknesses of the cover window 445 and the first attachment member 446 in the thickness direction (e.g., the first thickness direction (+Z direction) and/or the second thickness direction (−Z direction)) may correspond to the sum of the thicknesses of the protective layer 447 and the first portion 4481 of the second attachment member 441 and the first masking part 441 in the thickness direction (e.g., the first thickness direction (+Z direction) and/or the second thickness direction (−Z direction)).

FIG. 19 is a cross-sectional view illustrating an example foldable electronic device according to an embodiment.

For example, FIG. 19 is a cross-sectional view taken along line A-A′ of FIG. 5.

The detailed configuration of the foldable electronic device 501 according to an embodiment of the disclosure not, which is not described below, may be identical or similar to the detailed configuration of the electronic device 101 according to an embodiment of the disclosure described with reference to FIGS. 1 to 4, the detailed configuration of the foldable electronic device 301 according to an embodiment of the disclosure described with reference to FIGS. 5 to 15, and/or the detailed configuration of the foldable electronic device 401 according to an embodiment of the disclosure described with reference to FIGS. 16 to 18.

The detailed configuration of the display module 540 according to an embodiment of the disclosure, which is not described below, may be identical or similar to the detailed configuration of the display module 160 according to an embodiment of the disclosure described with reference to FIG. 1, the first display 230 according to an embodiment of the disclosure described with reference to FIGS. 2 to 4, and the detailed configuration of the display module 340 according to an embodiment of the disclosure described with reference to FIGS. 5 to 15, and/or the detailed configuration of the display module 440 according to an embodiment of the disclosure described with reference to FIGS. 16, 17 and 18.

According to an embodiment, the protective layer 547 may be disposed in an area overlapping the non-conductive member 530 in the thickness direction (e.g., the first thickness direction (+Z direction) and/or the second thickness direction (−Z direction)). For example, the boundary between the cover window 545 and the protective layer 547 may be formed at a position overlapping the non-conductive member 530. Accordingly, since the boundary between the cover window 545 and the protective layer 547 may be covered by the non-conductive member 530, appearance quality may be enhanced, and light leakage may be prevented or alleviated.

According to an embodiment, the masking part 549 may include a portion disposed between the cover window 545 and the first attachment member 546. For example, the masking part 549 may include a first masking part 5491 disposed between the protective layer 547 and the second attachment member 548. For example, the masking part 549 may include a third masking part 5493 disposed between the cover window 545 and the first attachment member 546. This structure may be one for securing an area to be covered by the masking part 549, even though the width of the protective layer 547 decreases.

According to an embodiment, the flexible display panel 542 may not emit light in an area between the first masking part 5491 and the third masking part 549. Since there may be a fine gap between the first masking part 5491 and the third masking part 549, light may be prevented/reduced from leaking out between the first masking part 5491 and the third masking part 5493 by not emitting light in an area corresponding to the gap formed between the first masking part 541 and the third masking part 5493 of the flexible display panel 542.

According to an embodiment, the flexible display panel 542 may be configured to output a color corresponding to the masking part 549 in an area between the first masking part 5491 and the third masking part 549. Accordingly, even when light leaks through the gap between the first masking part 5491 and the third masking part 549, the color of the leaking light corresponds to the color of the masking part 549, thereby preventing/reducing the appearance quality of the display module 540 from deteriorating due to the leaking light.

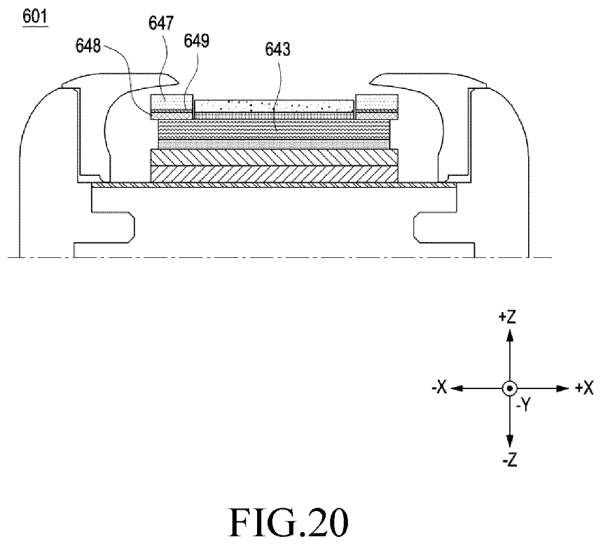

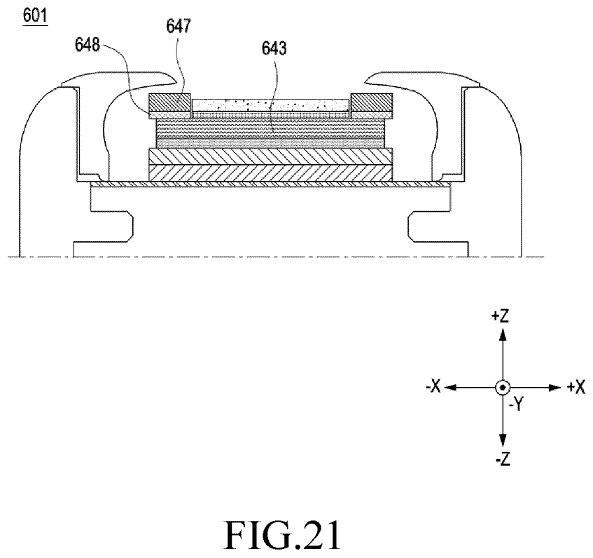

FIG. 20 is a cross-sectional view illustrating an example foldable electronic device according to an embodiment. FIG. 21 is a cross-sectional view illustrating an example foldable electronic device according to an embodiment.

For example, FIGS. 20 and 21 are cross-sectional views taken along line A-A′ of FIG. 5.

The detailed configuration of the foldable electronic device 601 according to an embodiment of the disclosure not, which is not described below, may be identical or similar to the detailed configuration of the electronic device 101 according to an embodiment of the disclosure described with reference to FIGS. 1 to 4, the detailed configuration of the foldable electronic device 301 according to an embodiment of the disclosure described with reference to FIGS. 5 to 15, the detailed configuration of the foldable electronic device 401 according to an embodiment of the disclosure described with reference to FIGS. 16, 17 and 18, and/or the detailed configuration of the foldable electronic device 501 according to an embodiment of the disclosure described with reference to FIG. 19.

The detailed configuration of the display module 640 according to an embodiment of the disclosure, which is not described below, may be identical or similar to the detailed configuration of the display module 160 according to an embodiment of the disclosure described with reference to FIG. 1, the detailed configuration of the first display module 230 according to an embodiment of the disclosure described with reference to FIGS. 2 to 4, the detailed configuration of the display module 340 according to an embodiment of the disclosure described with reference to FIGS. 16, 17 and 18, and/or the detailed configuration of the display module 440 according to an embodiment of the disclosure described with reference to FIG. 19.

According to an embodiment, the display module 640 may include a second attachment member 648. The second attachment member 648 may be disposed between the protective layer 647 and the glass layer 643. The second attachment member 648 may include a pressure-sensitive adhesive PSA. Accordingly, in the manufacturing process of the display module 640, since the protective layer 647 may be easily attached to the glass layer 643, manufacturing efficiency of the display module 640 may be enhanced.

According to an embodiment, as illustrated in FIG. 21, the protective layer 647 may have a color capable of blocking the passage of light or transmitting less light. In this case, the masking part 649 disclosed in FIG. 20 may not be provided. Through this structure, since the manufacturing operation for forming the masking part 649 may be omitted, manufacturing efficiency of the display module 640 may be enhanced, and manufacturing cost of the display module 640 may be decreased.

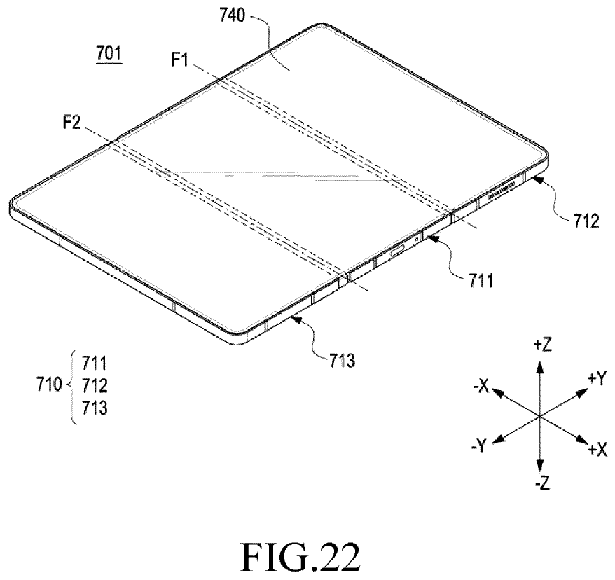

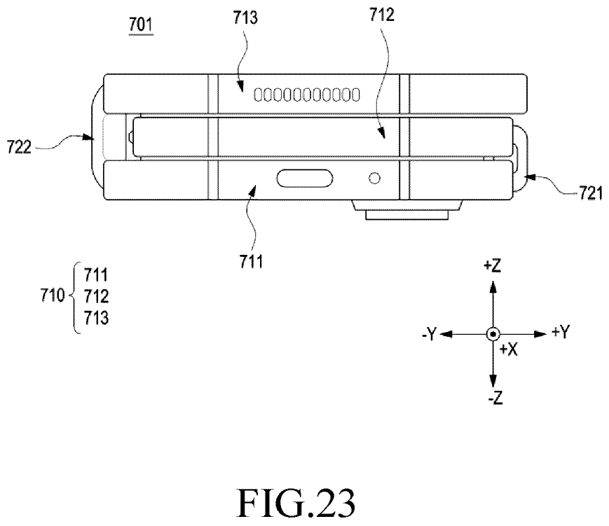

FIG. 22 is a perspective view illustrating an example foldable electronic device according to an embodiment. FIG. 23 is a diagram illustrating a side view of a foldable electronic device according to an embodiment.

Hereinafter, the ‘first lateral direction’ may refer, for example, to a direction parallel to the first folding axis F1 and the second folding axis F2, and may refer, for example, to the +X direction which is the lower right direction in FIG. 22. The ‘second lateral direction’ is a direction opposite to the first lateral direction (+X direction), and may refer, for example, to the −X direction, which is the left direction with respect to FIG. 22. The ‘third lateral direction’ is a lateral direction crossing the first lateral direction (+X direction) and/or the second lateral direction (−X direction) and may refer, for example, to the +Y direction which is the direction from the first housing part 711 to the second housing part 712 in FIG. 22. The ‘fourth lateral direction’ is a direction opposite to the third lateral direction (+Y direction), and may refer, for example, to the −Y direction, which is the direction from the first housing part 711 to the third housing part 713 in FIG. 22.

Hereinafter, the ‘first thickness direction’ is the direction of one thickness of the foldable housing 710 and/or the display module 740, and may refer, for example, to the +Z direction, which is the upward direction in FIG. 22. The ‘second thickness direction’ is a direction opposite to the first thickness direction (+Z1 direction), and may refer, for example, to the −Z1 direction which is the downward direction in FIG. 22. The thickness direction’ may refer, for example, to the first thickness direction (+Z direction) and/or the second thickness direction (−Z direction).

Hereinafter, the detailed configuration of the foldable electronic device 701 according to an embodiment of the disclosure, which is not described, may be identical to the detailed configuration of the electronic device 101 described with reference to FIGS. 1 to 4, the detailed configuration of the foldable electronic device 301 described with reference to FIGS. 5 to 15, the detailed configuration of the foldable electronic device 401 described with reference to FIGS. 16 to 18, the detailed configuration of the foldable electronic device 501 described with reference to FIGS. 19 and/or the detailed configuration of the foldable electronic device 601 described with reference to FIGS. 20 and 21.

According to an embodiment, the foldable electronic device 701 may include a foldable housing 710. The foldable housing 710 may form a space where the display module 740 is disposed.

According to an embodiment, the foldable housing 710 may include a first housing part 711, a second housing part 712, and a third housing part 713. The first housing part 711 may be disposed between the second housing part 712 and the third housing part 713. The second housing part 712 may be rotatably coupled to the first housing part 711. The third housing part 713 may be rotatably coupled to the first housing part 711.

According to an embodiment, the foldable electronic device 701 may include a display module 740. The display module 740 may be disposed on the first housing part 711, the second housing part 712, and the third housing part 713.

According to an embodiment, the foldable electronic device 701 may include a first hinge 721 and a second hinge 722. The first hinge 721 may be disposed between the first housing part 711 and the second housing part 712. The first hinge 721 may rotatably connect the first housing part 711 and the second housing part 712. The second hinge 722 may be disposed between the first housing part 711 and the third housing part 713. The second hinge 722 may rotatably connect the first housing part 711 and the third housing part 713.

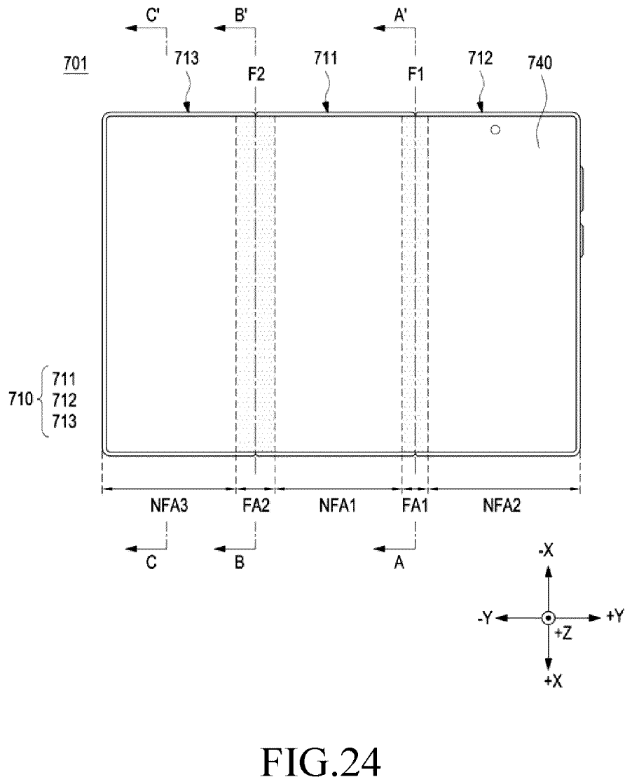

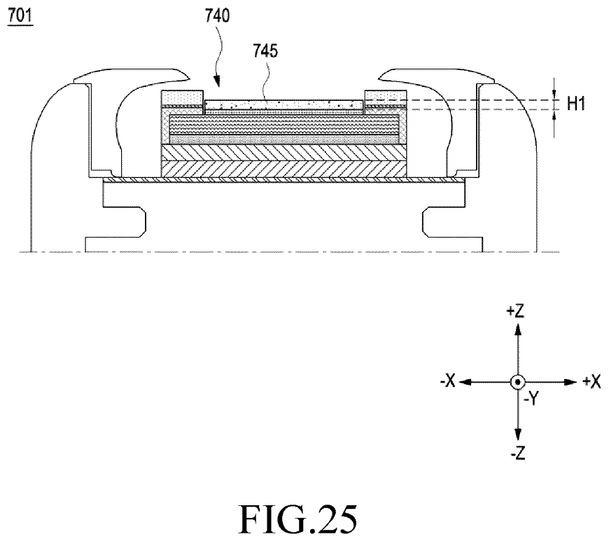

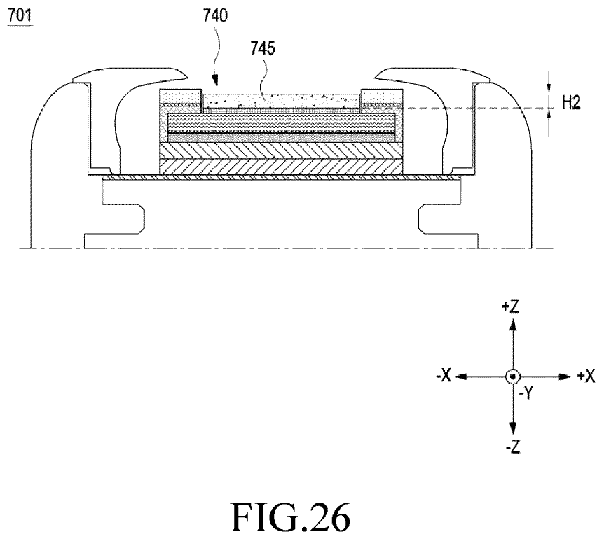

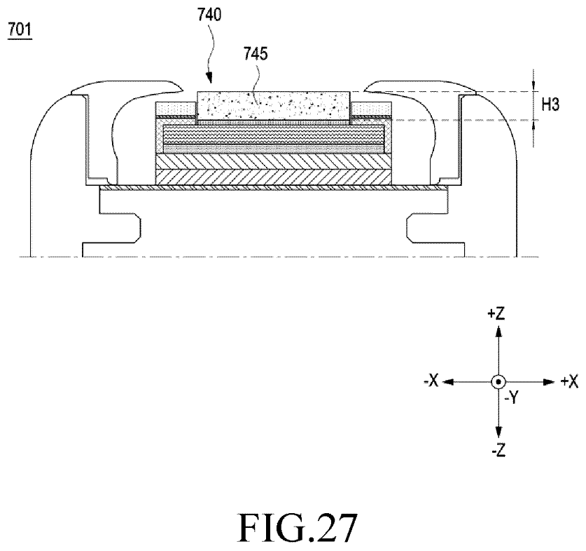

FIG. 24 is a diagram illustrating a plan view of an example foldable electronic device according to an embodiment. FIG. 25 is a cross-sectional view illustrating an example foldable electronic device according to an embodiment. FIG. 26 is a cross-sectional view illustrating an example foldable electronic device according to an embodiment. FIG. 27 is a cross-sectional view illustrating an example foldable electronic device according to an embodiment.

For example, FIG. 25 is a cross-sectional view taken along line A-A′ of FIG. 24, and is a cross-sectional view illustrating the first folding area FA1. FIG. 26 is a cross-sectional view taken along line B-B′ of FIG. 24, and is a cross-sectional view illustrating the second folding area FA2. FIG. 27 is a cross-sectional view taken along line C-C′ of FIG. 24, and is a cross-sectional view illustrating non-folding areas NFA1, NFA2, and NFA3 (e.g., the third non-folding area NFA3).

According to an embodiment, the display module 740 may include a first folding area FA1. The first folding area FA1 may be formed in an area adjacent to the first folding axis F1 positioned between the first housing part 711 and the second housing part 712. The first folding area FA1 may extend in parallel to the first folding axis F1. The first folding area FA1 may be bent when the foldable electronic device 701 is switched from an unfolded state (e.g., the state of FIG. 22) to a folded state (e.g., the state of FIG. 23).

According to an embodiment, the display module 740 may include a second folding area FA2. The second folding area FA2 may be formed in an area adjacent to the second folding axis F2 positioned between the second housing part 712 and the third housing part 713. The second folding area FA2 may extend in parallel to the second folding axis F2. The second folding area FA2 may be bent when the foldable electronic device 701 is switched from an unfolded state (e.g., the state of FIG. 22) to a folded state (e.g., the state of FIG. 23).

According to an embodiment, the display module 740 may include a first non-folding area NFA1. The first non-folding area NFA1 may be disposed between the first folding area FA1 and the second folding area FA2. The first non-folding area NFA1 may be an area overlapping the first housing part 711. The first non-folding area NFA1 may be a portion that is supported by the first housing part 711 and does not bend.

According to an embodiment, the display module 740 may include a second non-folding area NFA2. The second non-folding area NFA2 may be formed on the side in the third lateral direction (+Y direction) of the first folding area FA1. The second non-folding area NFA2 may be an area overlapping the second housing part 712. The second non-folding area NFA2 may be a portion that is supported by the second housing part 712 and does not bend.

According to an embodiment, the display module 740 may include a third non-folding area NFA3. The third non-folding area NFA3 may be formed on the side in the fourth lateral direction (−Y direction) of the second folding area FA2. The second non-folding area NFA2 may be an area overlapping the third housing part 713. The third non-folding area NFA3 may be a portion that is supported by the third housing part 713 and does not bend.

According to an embodiment, when the foldable electronic device 701 is in a folded state (e.g., the state of FIG. 23), each of the first housing part 711, the second housing part 712, and the third housing part 713 may be disposed in one direction (e.g., the first thickness direction (+Z direction)). For example, the second housing part 712 may be disposed on the first housing part 711, and the third housing part 713 may be disposed on the second housing part 712. The second housing part 712 may be disposed between the first housing part 711 and the third housing part 713.

According to an embodiment, the width (e.g., the length in the third lateral direction (+Y direction) and/or the fourth lateral direction (−Y direction)) of the first folding area FA1 may be smaller than the width (e.g., the length in the third lateral direction (+Y direction) and/or the fourth lateral direction (−Y direction)) of the second folding area FA2. For example, when the foldable electronic device 701 is in a folded state (e.g., the state of FIG. 23), the distance between the third housing part 713 and the first housing part 711 may be larger than the distance between the second housing part 712 and the first housing part 711, so that the width of the second folding area FA2 may be larger than the width of the first folding area FA1. Accordingly, when the foldable electronic device 701 is in a folded state (e.g., the state of FIG. 23), the radius of curvature of the display module 740 in the first folding area FA1 may be smaller than the radius of curvature of the display module 740 in the second folding area FA2.

According to an embodiment, the thickness (e.g., H1 of FIG. 25) (e.g., the length in the first thickness direction (+Z direction) and/or the second thickness direction (−Z direction)) of the cover window 745 of the second folding area FA2 may be smaller than the thickness (e.g., H2 of FIG. 26) (e.g., the length in the first thickness direction (+Z direction) and/or the second thickness direction (−Z direction)) of the cover window 745 of the second folding area FA2. Accordingly, when the foldable electronic device 701 is in a folded state (e.g., the state of FIG. 23), the stress acting on the display module 740 may be decreased in the first folding area FA1 where the display module 740 bends more than the second folding area FA2.

According to an embodiment, the thicknesses of the cover window 745 in the first folding area FA1 and the second folding area FA2 (e.g., H1 of FIGS. 25 and H2 of FIG. 26) (e.g., the length in the first thickness direction (+Z direction) and/or the second thickness direction (−Z direction)) may be smaller than the thickness of the cover window (e.g., H3 of FIG. 27) (e.g., the length in the first thickness direction (+Z direction) and/or the second thickness direction (−Z direction)) in the non-folding areas NFA1, NFA2, and NFA3. Accordingly, it is possible to secure sufficient rigidity of the display module 740 in the non-folding areas NFA1, NFA2, and NFA3 where creasing is less likely as the display module 740 is not bent while mitigating creasing of the display module 740 by reducing the stress acting on the display module 740 in the first and second folding areas FA1 and FA2.

The flexible display module mounted in the foldable electronic device includes various layers. For example, the flexible display module includes various soft layers, such as a protective layer, a replaceable cover window, and/or an adhesive layer for bonding the layers. These soft layers are formed of polymers, making them vulnerable to plastic deformation. As the foldable electronic device is repeatedly folded and unfolded, the layers in the display module may experience continuous compressive or tensile stress, leading to the formation of creases due to plastic deformation. This may ultimately deteriorate the usability and appearance of the device.

Conventional flexible display modules had a structure in which a protective layer and a cover window which is replaceable are simply stacked by an adhesive layer on a thin film glass layer. As a result, the stress acting on the display module may increase during folding of the display module due to the thickening of the display module, worsening the creasing issue. Further, a difference in the degree of plastic deformation occurs between the layers due to a difference in tensile or compressive deformation amount between the layers, resulting in formation of more creases.

The disclosure provides a structure that may prevent and/or reduce creases from forming on the display module, while also retaining the functionality of the traditional protective layer and replaceable cover window.

The disclosure is not limited, but may rather be diverse without departing from the spirit and scope of the disclosure.

The foldable electronic device according to an embodiment of the disclosure may prevent and/or reduce creases from forming on the display module, while also retaining the functionality of the traditional protective layer and replaceable cover window.

Effects obtainable from the disclosure are not limited to the above-mentioned effects, and other effects not mentioned may be apparent to one of ordinary skill in the art from the description.

A foldable electronic device according to an example embodiment of the disclosure may comprise a foldable housing comprising a first housing part and a second housing part.

The foldable electronic device according to an example embodiment of the disclosure may comprise a hinge module comprising a hinge connected to the first housing part and the second housing part, and configured to rotatably connect the first housing part and the second housing part about a folding axis positioned between the first housing part and the second housing part.

The foldable electronic device according to an example embodiment of the disclosure may comprise a display module comprising a display disposed on the first housing part and the second housing part.

The display module of the foldable electronic device according to an example embodiment of the disclosure may comprise a flexible display panel.

The display module of the foldable electronic device according to an example embodiment of the disclosure may comprise a glass layer disposed on the flexible display.

The display module of the foldable electronic device according to an example embodiment of the disclosure may comprise a cover window attached on the glass layer via a first attachment member comprising an adhesive material having a first attaching force in a central area of the display module.

The display module of the foldable electronic device according to an example embodiment of the disclosure may comprise a protective layer disposed adjacent to a side surface of the cover window in an edge area of the display module formed on an outside of the central area and attached on the glass layer via a second attachment member comprising an adhesive material having a second attaching force stronger than the first attaching force.

In the foldable electronic device according to an example embodiment of the disclosure, the second attachment member may comprise a first portion configured to cover a portion of an upper surface of the glass layer and a second portion configured to cover a side surface of the glass layer.

In the foldable electronic device according to an example embodiment of the disclosure, a portion of an edge of the cover window may protrude above the protective layer.

In the foldable electronic device 301, 401 according to an embodiment of the disclosure, the display module may comprise a display including a folding area formed in an area adjacent to the folding axis and configured to bend during a process in which the foldable electronic device changes from an unfolded stated to a folded stated, and a non-folding area formed on a side farther from the folding axis based on the folding area.

In the foldable electronic device according to an example embodiment of the disclosure, in at least a portion of the non-folding area, an upper surface of the cover window may be formed in a position protruding more than an upper surface 3471, 447 of the protective layer.

In the foldable electronic device according to an example embodiment of the disclosure, in the folding area, the upper surface of the cover window may be formed in a position recessed more than the upper surface of the protective layer.

In the foldable electronic device according to an example embodiment of the disclosure, the side surface of the cover window may comprise a first inclined surface inclined such that an upper surface of the cover window has a first width and a lower surface of the cover window has a second width smaller than the first width.

In the foldable electronic device according to an example embodiment of the disclosure, a side surface, facing the cover window, of the protective layer may comprise a second inclined surface inclined corresponding to the first inclined surface such that an upper surface of the protective layer has a third width and a lower surface of the protective layer has a fourth width larger than the third width.

In the foldable electronic device according to an example embodiment of the disclosure, the display module may further comprise a masking portion, at least a portion of the masking portion is disposed between the protective layer and the second attachment member.

In the foldable electronic device according to an example embodiment of the disclosure, the masking portion may comprise a first masking part disposed between the protective layer and the second attachment member, and a second masking part disposed between the cover window and the protective layer.

In the foldable electronic device according to an example embodiment of the disclosure, the side surface of the cover window may comprise a first inclined surface inclined such that an upper surface of the cover window has a first width and a lower surface of the cover window has a second width smaller than the first width.

In the foldable electronic device according to an example embodiment of the disclosure, the second masking part may comprise a portion inclined corresponding to the first inclined surface.

The foldable electronic device according to an example embodiment of the disclosure may further comprise a non-conductive member comprising a non-conductive material disposed along an edge of the foldable housing and configured to cover an edge portion of the display module.

In the foldable electronic device according to an example embodiment of the disclosure, the display module may at least partially overlap the non-conductive member in a thickness direction of the foldable housing.

In the foldable electronic device according to an example embodiment of the disclosure, the protective layer may comprise an overlapping portion overlapping the non-conductive member in the thickness direction, and a non-overlapping portion formed in an inner side of the overlapping portion.

In the foldable electronic device according to an example embodiment of the disclosure, the protective layer may be disposed in an area overlapping the non-conductive member in the thickness direction.

In the foldable electronic device according to an example embodiment of the disclosure, the display module may comprise a masking part comprising a first masking part disposed between the protective layer and the second attachment member, and a third masking part adjacent to the first masking part and disposed between the cover window and the first attachment member.

In the foldable electronic device according to an example embodiment of the disclosure, in an area between the first masking part and the third masking part, the flexible display panel may be configured to not emit light or to output a color corresponding to the masking part.

In the foldable electronic device according to an example embodiment of the disclosure, the first attachment member may comprise a pressure-sensitive adhesive.

In the foldable electronic device according to an example embodiment of the disclosure, the second attachment member may comprise an optical clear adhesive.

In the foldable electronic device according to an example embodiment of the disclosure, the optical clear adhesive may comprise an optical clear resin.

A display module according to an example embodiment of the disclosure may comprise a flexible display panel.

The display module according to an example embodiment of the disclosure may comprise a glass layer disposed on the flexible display.

The display module according to an example embodiment of the disclosure may comprise a cover window attached on the glass layer via a first attachment member comprising an adhesive material having a first attaching force in a central area of the display module.

The display module according to an example embodiment of the disclosure may comprise a protective layer disposed adjacent to a side surface of the cover window in an edge area of the display module formed on an outside of the central area and attached on the glass layer via a second attachment member comprising an adhesive material having a second attaching force stronger than the first attaching force.

In the display module according to an example embodiment of the disclosure, the second attachment member may comprise a first portion configured to cover a portion of an upper surface of the glass layer and a second portion configured to cover a side surface of the glass layer. In the display module 340, 440, 50 according to an example embodiment of the disclosure, a portion of an edge of the cover window may protrude above the protective layer.

In the display module according to an example embodiment of the disclosure, the side surface of the cover window may comprise a first inclined surface inclined such that an upper surface of the cover window has a first width and a lower surface of the cover window has a second width smaller than the first width.

In the display module according to an example embodiment of the disclosure, a side surface, facing the cover window, of the protective layer may comprise a second inclined surface inclined corresponding to the first inclined surface such that an upper surface of the protective layer has a third width and a lower surface of the protective layer has a fourth width larger than the third width.

While the disclosure has been illustrated and described with reference to an example embodiment, it will be understood that the an example embodiment are intended to be illustrative, not limiting. It will be further understood by those skilled in the art that various modifications, alternatives and/or variations of the an example embodiment may be made without departing from the true technical spirit and full technical scope of the disclosure, including the appended claims and their equivalents. It will also be understood that any of the embodiment(s) 10 described herein may be used in conjunction with any other embodiment(s) described herein.

What is claimed is:

1. A foldable electronic device comprising:
a foldable housing comprising a first housing part and a second housing part;
a hinge module comprising a hinge connected to the first housing part and the second housing part, and configured to rotatably connect the first housing part and the second housing part about a folding axis positioned between the first housing part and the second housing part; and
a display module comprising a display disposed on the first housing part and the second housing part,
wherein the display module further includes
a flexible display panel;
a glass layer disposed on the flexible display;
a cover window attached on the glass layer via a first attachment member comprising an adhesive material having a first attaching force in a central area of the display module; and
a protective layer disposed adjacent to a side surface of the cover window in an edge area of the display module formed on an outside of the central area and attached on the glass layer via a second attachment member comprising an adhesive material having a second attaching force stronger than the first attaching force.

2. The foldable electronic device of claim 1,
wherein the second attachment member comprises a first portion covering a portion of an upper surface of the glass layer and a second portion covering a side surface of the glass layer.

3. The foldable electronic device of claim 1,
wherein a portion of an edge of the cover window protrudes above the protective layer.

4. The foldable electronic device of claim 1,
wherein the display module comprises a folding area formed in an area adjacent to the folding axis and configured to bend during a process in which the foldable electronic device changes from an unfolded stated to a folded stated, and a non-folding area formed on a side farther from the folding axis based on the folding area,
wherein, in at least a portion of the non-folding area, an upper surface of the cover window is formed in a position protruding more than an upper surface of the protective layer, and
wherein, in the folding area, the upper surface of the cover window is formed in a position recessed more than the upper surface of the protective layer.

5. The foldable electronic device of claim 1,
wherein the side surface of the cover window comprises a first inclined surface inclined such that an upper surface of the cover window has a first width and a lower surface of the cover window has a second width smaller than the first width.

6. The foldable electronic device of claim 5,
wherein a side surface, facing the cover window, of the protective layer comprises a second inclined surface inclined corresponding to the first inclined surface such that an upper surface of the protective layer has a third width and a lower surface of the protective layer has a fourth width larger than the third width.

7. The foldable electronic device of claim 1,
wherein the display module further comprises a masking part, at least a portion of the masking part is disposed between the protective layer and the second attachment member.

8. The foldable electronic device of claim 7,
wherein the masking part comprises a first masking part disposed between the protective layer and the second attachment member, and a second masking part disposed between the cover window and the protective layer.

9. The foldable electronic device of claim 8,
wherein the side surface of the cover window comprises a first inclined surface inclined such that an upper surface of the cover window has a first width and a lower surface of the cover window has a second width smaller than the first width, and
wherein the second masking part comprises a portion inclined corresponding to the first inclined surface.

10. The foldable electronic device of claim 1, further comprising:
a non-conductive member comprising a non-conductive material disposed along an edge of the foldable housing and configured to cover an edge portion of the display module,
wherein the display module at least partially overlaps the non-conductive member in a thickness direction of the foldable housing.

11. The foldable electronic device of claim 10,
wherein the protective layer comprises an overlapping portion overlapping the non-conductive member in the thickness direction, and a non-overlapping portion formed in an inner side of the overlapping portion.

12. The foldable electronic device of claim 10,
wherein the protective layer is disposed in an area overlapping the non-conductive member in the thickness direction, and
wherein the display module comprises a masking part comprising a first masking part disposed between the protective layer and the second attachment member, and a third masking part adjacent to the first masking part and disposed between the cover window and the first attachment member.

13. The foldable electronic device of claim 12,
wherein, in an area between the first masking part and the third masking part, the flexible display panel is configured to not emit light or to output a color corresponding to the masking part.

14. The foldable electronic device of claim 1,
wherein the first attachment member comprises a pressure-sensitive adhesive, and
wherein the second attachment member comprises an optical clear adhesive.

15. The foldable electronic device of claim 14,
wherein the optical clear adhesive comprises an optical clear resin.

16. A display module, comprising:
a flexible display panel;
a glass layer disposed on the flexible display;
a cover window attached on the glass layer via a first attachment member comprising an adhesive material having a first attaching force in a central area of the display module; and
a protective layer disposed adjacent to a side surface of the cover window in an edge area of the display module formed on an outside of the central area and attached on the glass layer via a second attachment member comprising an adhesive material having a second attaching force stronger than the first attaching force.

17. The display module of claim 16,
wherein the second attachment member comprises a first portion covering a portion of an upper surface of the glass layer and a second portion covering a side surface of the glass layer.

18. The display module of claim 16,
wherein a portion of an edge of the cover window protrudes above the protective layer.

19. The display module of claim 16,
wherein the side surface of the cover window comprises a first inclined surface inclined such that an upper surface of the cover window has a first width and a lower surface of the cover window has a second width smaller than the first width.

20. The display module of claim 19,
wherein a side surface, facing the cover window, of the protective layer comprises a second inclined surface inclined corresponding to the first inclined surface such that an upper surface of the protective layer has a third width and a lower surface of the protective layer has a fourth width larger than the third width.
